(19) United States
(12) Patent Application Publication
(10) Pub. No.: US 2025/0392262 A1
(43) Pub. Date: Dec. 25, 2025

(54) RF AMPLIFIER SYSTEM HAVING A HYBRID SUPPLY GENERATOR/MODULATOR

(71) Applicant: Murata Manufacturing Co., Ltd., Kyoto (JP)

(72) Inventors: David J. Perreault, Cambridge, MA (US); John R. Hoversten, Arlington, MA (US); Yevgeniy A. Tkachenko, Belmont, MA (US)

(73) Assignee: Murata Manufacturing Co., Ltd., Kyoto (JP)

(21) Appl. No.: 18/753,510

(22) Filed: Jun. 25, 2024

(51) Int. Cl. H03F 1/02; H03F 3/195; H03F 3/24

(52) U.S. Cl. CPC H03F 1/0227; H03F 3/195; H03F 3/245; H03F 2200/451

(57) ABSTRACT

In some embodiments, a system comprises: a hybrid supply generator/modulator comprising: an input to receive an input voltage; an output to provide a modulated voltage; a multi-output regulation stage configured to provide two intermediate voltages having voltage levels different from each other, at least one of the two intermediate voltages synthesized from the input voltage; and a multilevel converter configured to receive the two intermediate voltages and to generate the modulated voltage having a voltage level corresponding to one of the two intermediate voltage levels or at least one synthesized voltage level different from both intermediate voltage levels; and circuitry coupled to the output of the hybrid supply generator/modulator and to a power supply terminal of at least one radio frequency (rf) amplifier, the circuitry configured to modify the modulated voltage supplied to the at least one rf amplifier.

### BACKGROUND

The efficiency of radio-frequency (rf) power amplifiers (PAs) can be improved through “supply modulation” (or “drain modulation” or “collector modulation”), in which the power supply voltage provided to the PA is adjusted dynamically (“modulated”) over time depending upon the rf signal being synthesized. For the largest efficiency improvements, supply voltage can be adjusted discretely (among discrete levels) or continuously on a short time scale that tracks or dynamically accommodates rapid variations in rf signal amplitude (or envelope), such as may occur as data is encoded in the rf signal or as the rf signal amplitude is desired to be changed with high envelope bandwidth (e.g., as in envelope tracking, envelope tracking advanced, polar modulation, “class G” power amplification, multilevel backoff, multilevel LINC, Asymmetric Multilevel Outphasing, etc.). The power supply voltage (or voltage levels) provided to the PA may also be adapted to accommodate longer-term changes in desired rf envelope (e.g., “adaptive bias”) such as associated with adapting transmitter output strength to minimize errors in data transfer, for rf “traffic” variations, etc.

“Continuous” supply modulation (e.g., “envelope tracking” or “adaptive bias”) may be advantageously realized by dynamically selecting an intermediate voltage from among a set of discrete power supply voltages and then further regulating (stepping down) this intermediate voltage to create a continuously-variable supply voltage to be provided to the PA, or by pulse-width modulating between two or more levels and filtering the output to create a continuously-varying waveform.

Some rf amplifier systems utilize “discrete” supply modulation (or discrete “drain modulation”) in which the supply voltage is switched among a set of discrete voltage levels, possibly including additional filtering or modulation to shape the voltage transitions among levels. Systems of this type include “class G” amplifiers, multilevel LINC (MLINC) Power Amplifiers, Asymmetric Multilevel Outphasing (AMO) Power Amplifiers, Multilevel Backoff amplifiers (including “Asymmetric Multilevel Backoff” amplifiers) and digitized polar transmitters among other types. Hybrid systems which utilize a combination of continuous and discrete supply modulation may also be realized.

### SUMMARY

Described are concepts, systems, circuits, devices and techniques for use in and/or with PA architectures using supply modulation. The described concepts, systems, circuits, devices and techniques can provide both very rapid variations in modulated power supply voltage (e.g., among multiple discrete levels) while also providing the ability to slowly adapt the voltages of the discrete levels over a desired range. Such concepts, systems, circuits, devices and techniques find use in a number of applications including, but not limited to PA architectures.

Using descried concepts, systems, circuits, devices and techniques, it is possible to efficiently and compactly generate a set of m power supply voltages. Two of the m power supply voltages (e.g., V₁ and Vₘ) can be independently controlled. The other m-2 power supply voltages can be distributed in some prescribed relation to the two independently controlled power supply voltages, such as spaced in an even fashion between them and/or around them (e.g., with adjacent voltage levels each separated by an approximate voltage ΔV). Thus, for example, the following m power supply voltages can be provided wherein V₁ and Vₘ are the independently controlled supply voltages:

$${V}_{k} = {V}_{1} + ( k - 1 ) \cdot ( {V}_{m} - {V}_{1} ) / ( m - 1 ) for k = 1 … m .$$

Such an arrangement is equivalent to allowing for independently specifying or controlling:
(a) minimum (Vₘᵢₙ) and maximum (Vₘₐₓ) voltage levels (with the spacing between voltage levels ΔV determined in terms of Vₘᵢₙ and Vₘₐₓ and the total number of levels m).
(b) the minimum supply voltage level (Vₘᵢₙ) and the inter-level voltage spacing ΔV (with the maximum voltage level Vₘₐₓ determined by ΔV and the total number of levels m.)
(c) the maximum supply voltage level (Vₘₐₓ) and the inter-level voltage spacing ΔV (with the minimum voltage level Vₘᵢₙ determined by ΔV and the total number of levels m.)

The concepts, systems, circuits, devices and techniques described herein provide substantially all (or most) of the practical benefits available from supply modulation (e.g., in terms of PA efficiency) while at the same time avoiding limitations associated with providing truly independent voltage level control or ratiometric levels. Thus, the concepts, systems, circuits, devices and techniques described herein provide significant advantages in combinations of size, cost, efficiency and performance as compared to existing approaches.

Further benefits are provided if one only need generate two regulated supply voltages and be able to directly provide one or more additional supply voltage levels to the PA, without the necessity of having a separate supply generator element to generate these additional levels cascaded with a supply modulator to select among the levels. Merging the functions of intermediate level generation and supply modulation can reduce the number and size of passive components (e.g., capacitors) required as well as the number, required area and loss of semiconductor elements (e.g., switches).

According to an aspect of the present disclosure, a system comprises: a hybrid supply generator/modulator comprising: an input to receive an input voltage; an output to provide a modulated voltage; a multi-output regulation stage configured to provide two intermediate voltages having voltage levels different from each other, at least one of the two intermediate voltages synthesized from the input voltage; and a multilevel converter configured to receive the two intermediate voltages and to generate the modulated voltage having a voltage level corresponding to one of the two intermediate voltage levels or at least one synthesized voltage level different from both intermediate voltage levels; and circuitry coupled to the output of the hybrid supply generator/modulator and to a power supply terminal of at least one radio frequency (rf) amplifier, the circuitry configured to modify the modulated voltage supplied to the at least one rf amplifier.

In some embodiments, the circuitry comprises a disconnect switch configured to selectively supply a zero voltage level to the at least one rf amplifier. In some embodiments, the circuitry comprises a disconnect switch configured to selectively isolate the output of the hybrid supply generator/modulator from the at least one rf amplifier. In some embodiments, the disconnect switch is configured to be actuated in conjunction with enabling or disabling the rf amplifier.

In some embodiments, the circuitry comprises a pulse shaping network (PSN) configured to filter the modulated voltage. In some embodiments, the PSN includes at least one passive element. In some embodiments, the at least one passive element is realized as a discrete element. In some embodiments, the at least one passive element is realized on an integrated circuit (IC) or module. In some embodiments, the at least one passive element results from parasitic resistance, inductance, or capacitance. In some embodiments, the PSN includes: first and second inductors connected in series between the output of the hybrid supply generator/modulator and the power supply terminal of the at least one rf amplifier; a capacitor having a first terminal connected between first and second inductors; and a third inductor connected between a second terminal of capacitor and ground.

In some embodiments, the PSN includes: a resistor having a first terminal connected to the output of the hybrid supply generator/modulator; and a capacitor having a first terminal connected to a second terminal of the resistor and a second terminal connected to ground. In some embodiments, the PSN includes: a capacitor having a first terminal connected to the output of the hybrid supply generator/modulator and a second terminal connected to ground; and a resistor having a first terminal connected to the first terminal of the capacitor.

In some embodiments, the circuitry further comprises a switching network. In some embodiments, the switching network is configured such that in a first state, the switching network provides a first signal path having a first filter configuration between the output of the hybrid supply generator/modulator and the power supply terminal of the at least one rf amplifier, and in a second state, the switching network provides a second signal path having a second, different filter configuration between the output of the hybrid supply generator/modulator and the and the power supply terminal of the at least one rf amplifier. In some embodiments, the switching network comprises at least one passive element having a first terminal connected to the output of the hybrid supply generator/modulator, a switching network configured such that in a first state the switching network connects a second terminal of the at least one passive element to ground, and in a second state, the switching network disconnects the second terminal of the at least one passive element from ground.

In some embodiments, the switching network is coupled in a cascaded configuration with the hybrid supply generator/modulator. In some embodiments, the switching network is coupled across the PSN and configured to selectively provide a signal path which bypasses the PSN. In some embodiments, the switching network is coupled in parallel with a passive element of the PSN and configured to alter a transfer function of the PSN by selectively shorting at least one passive element. In some embodiments, the switching network comprises plurality of switches and at least a first set of the plurality of switches are located on a first integrated circuit die and at least a second set of the plurality of switches are located on a second, different integrated circuit die.

According to another aspect of the present disclosure, a system comprises: a hybrid supply generator/modulator comprising: an input to receive an input voltage; an output to provide a modulated voltage; a multi-output regulation stage configured to provide two intermediate voltages having voltage levels different from each other, at least one of the two intermediate voltages synthesized from the input voltage; and a multilevel converter configured to receive the two intermediate voltages and to generate the modulated voltage having a voltage level corresponding to one of the two intermediate voltage levels or at least one synthesized voltage level different from both intermediate voltage levels, wherein the output of the hybrid supply generator/modulator is directly or indirectly coupled to a power supply input of at least one radio frequency (rf) amplifier.

According to another aspect of the present disclosure, a method is provided for change a frequency response of circuit coupled to an output of a hybrid supply generator/modulator and to a radio frequency (rf) amplifier, the method comprising: in a first state, configuring the circuit to provide a first signal path having a first filter configuration between the hybrid supply generator/modulator output and the rf amplifier input; and in a second state, configuring the circuit to provide a second signal path having a second, different filter configuration between the hybrid supply generator/modulator output and the rf amplifier input.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1A is a block diagram of an rf amplifier system utilizing multiple supply levels which may supply multiple PAs.

FIG. 1B is a block diagram of an rf amplifier system utilizing multiple supply levels and implemented as a single-inductor multiple-output boost converter as a supply generator, a parallel supply modulator and an LC filter.

FIG. 2A is a schematic diagram of an illustrative switching network provided as a series supply modulator.

FIG. 2B is a schematic diagram of an illustrative switching network provided as a parallel supply modulator.

FIG. 3 is a block diagram of a supply modulator with a cascaded turn-off switch.

FIG. 4 is a schematic diagram of an illustrative implementation of the series modulator of FIG. 2A.

FIG. 5 is a block diagram of an rf amplifier system utilizing a hybrid supply generator/modulator to provide multiple supply levels.

FIG. 5A is a block diagram of an rf amplifier system having a hybrid supply generator/modulator and a filter network.

FIG. 5B is a block diagram of an rf amplifier system having a hybrid supply generator/modulator and a PA turn-off switch.

FIG. 6 is a block diagram illustrating an architecture of a hybrid supply generator/supply modulator suitable for use in an rf amplifier system.

FIG. 6A is a block diagram of another hybrid supply generator/supply modulator architecture wherein one of the intermediate voltages corresponds to the input voltage.

FIGS. 7A-E are schematic diagrams illustrating implementations of a multi-output regulation stage suitable for use in a hybrid supply generator/supply modulator.

FIG. 8 is a schematic diagram of a differential multilevel converter suitable for use in a hybrid supply generator/supply modulator, the converter capable of providing three (3) effective output levels using four (4) switch states.

FIGS. 9 and 9A are diagrams of state machines that can be used for controlling switch state in the differential multilevel converter of FIG. 8.

FIGS. 10A-10C are a series of plots illustrating voltage patterns and state transitions associated with the state machine of FIG. 9.

FIG. 11 is a schematic diagram of a differential multilevel converter suitable for use in a hybrid supply generator/supply modulator, the converter capable of providing four (4) effective output levels using eight (8) switch states.

FIGS. 12A and 12B are diagrams of state machines that can be used for controlling switch state in the differential multilevel converter of FIG. 11.

FIGS. 13A and 13B are schematic diagrams of differential multilevel converters suitable for use in a hybrid supply generator/supply modulator, the converters having circuitry to regulate charge on a flying capacitor.

FIG. 14 is a schematic diagram of an RF power amplifier system having a hybrid supply generator/supply modulator with multiple outputs to supply multiple power amplifiers.

FIG. 14A is a schematic diagram of an RF power amplifier system having multiple differential multilevel converters magnetically coupled to supply a single power amplifier.

FIG. 15 is a schematic diagram of a switching network having one or more pulse-shaping networks (PSNs) and being coupled to one or more hybrid supply generator/supply modulators.

### DETAILED DESCRIPTION

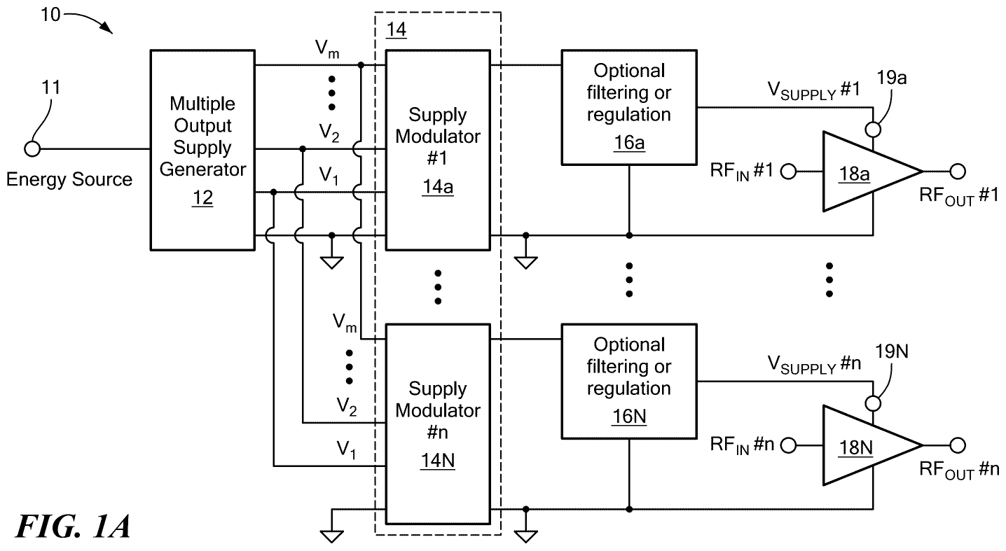

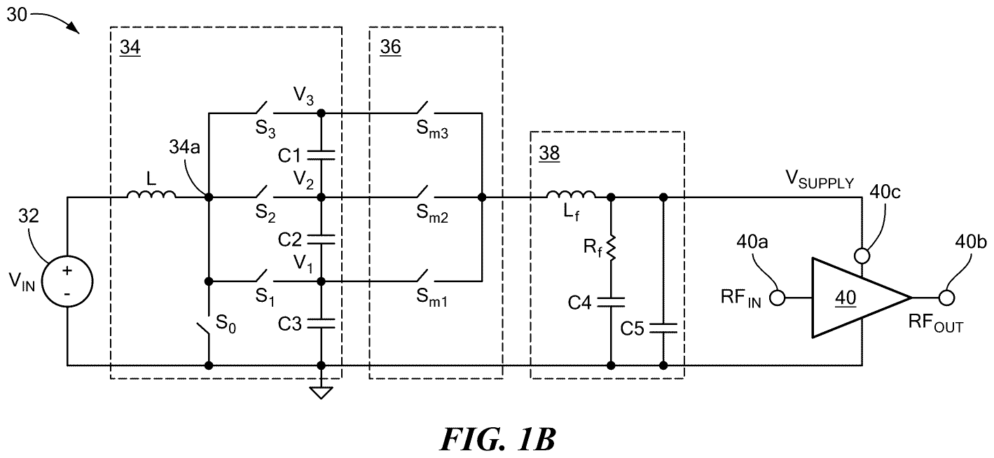

Referring now to FIG. 1A, shown is an overview of an illustrative rf power amplifier system architecture utilizing supply modulation wherein a supply modulator switches among multiple voltages generated by a separate supply generator (elements and aspects signal processing and control for such a system are omitted for clarity).

Illustrative system 10 includes a multiple output supply generator subsystem (or more simply a “supply generator”) 12 that can synthesize multiple power supply voltages V₁-Vₘ from a single input source 11. In some examples, supply generator 12 may regulate one or more of power supply voltages V₁-Vₘ. Supply generator 12 provides one or more of the voltages V₁-Vₘ, to inputs of one or more supply modulators subsystems (or more simply “supply modulators”) 14a-14N of a supply modulator system 14. Supply modulators 14a-14N can switch (and ideally, rapidly switch) among the different power supply voltages provided thereto by supply generator 12 to thus provide modulated supply voltages V_{supply #1}-V_{supply #N} at an output thereof. Switches may be modulated sufficiently rapidly to provide a power supply voltage to the PA such that the PA can provide the required rf output envelope while maintaining high efficiency, in accordance with techniques known in the art as discrete drain modulation, envelope tracking advanced (ETA), discrete envelope tracking, and digital envelope tracking (digital ET). Such techniques are described, for example, in one or more of U.S. Pat. Nos. 8,829,993; 9,160,287; 9,166,536; 9,172,336; 9,209,758; 9,755,672. The supply voltage inputs may be coupled to supply terminals of respect ones of one or more PAS 18a-18N. In some examples, PAs 18a-18N may be provided as rf power amplifiers. In some examples, supply generator 12 may supply the same or different voltages to supply modulators 14. In some examples, supply generator 12 a different number of voltages may be coupled between supply generator 12 and supply modulators 14.

In some examples, some or all of the supply voltages may be coupled to the supply terminals of the PAs through respective ones of optional filtering or voltage regulation stages 16a-16N. The filtering/regulation stages 16a-16N may comprise filtering networks, including passive filters and/or active filters and/or additional means of regulating the voltage (e.g., including low-dropout regulator(s), LDOs) to the PA, V_{supply}, from the modulated voltage, V_{mod}.

In some examples, one, some or all of the supply modulator subsystems 14a-14N may comprise one or more switches to couple one or more voltages provided by supply generator 12 to PA supply terminals 19a-9N. A variety of different switching circuits (i.e. switches having a wide a variety of switch configurations or switch topologies) may be utilized to realize supply modulator subsystems 14. For example, a supply modulator subsystem may comprise a plurality of serially coupled switches configured to provide a “series” modulator. Alternatively, a supply modulator subsystem may comprise a plurality of parallel coupled switches configured to provide a “parallel” modulator. Alternatively still, a supply modulator subsystem may comprise one or more serially coupled switches and one or more parallel coupled switches.

It is appreciated that the manner in which the voltages are synthesized by the supply generator affects the required ratings of the switches in the one or more supply modulators 14a-14N. This can be an important consideration as the required voltage ratings of the modulator switches can influence (and in some cases, highly influence) switching speed (and achievable modulation rate) and modulator efficiency, both of which are significant system factors. Regardless of the modulator switch topology used, if there are m supply levels ordered in increasing voltage V₁, . . . , Vₘ (i.e. V₁<V₂< . . . <Vₘ), the plurality (or chain) of switches coupled between the j^{th} supply voltage Vⱼ and the output V_{mod} may ideally be rated to block at least a negative voltage of magnitude (Vₘ−Vⱼ) and a positive voltage that is either (Vⱼ−V₁) or Vⱼ depending upon whether the modulator sources a lowest voltage Vⱼ or should ideally be able to directly supply zero volts to the PA. In some examples having designs of the latter type, where the power supply provided to the PA needs to be “cut off” (discharged to a zero volt power supply), a separate low-frequency “turn-off” or “disconnect” switch can be advantageously placed in series with the output of a supply modulator capable of sourcing modulator output voltages V₁, . . . , Vₘ. Such a turn-off switch can reduce the modulator switch chain voltage blocking requirements from Vⱼ to (Vⱼ-V₁); this can be advantageous for modulator design. Thus,

In some examples, an rf power amplifier system such as system 10 may comprise a “series” modulator in a form suitable for integrated circuit (IC) fabrication and for use with ratiometric supply voltages (e.g., V₂=2V₁, V₃=3V₁, V₄=4V₁). Such a design illustrates the impact of the supply levels on the required voltage rating of individual modulator devices; by correct selection of the level voltages, the best use of integrated CMOS processes can be made using both core devices and extended voltage devices to achieve the required voltage blocking characteristics of the modulator switch chains. Moreover, such a circuit illustrates the use of the generated levels for gate drive of the devices. This type of drive approach facilitates high efficiency and switching speed. However, to take advantage of driving the device gates between adjacent level voltages (e.g., between Vⱼ and Vⱼ₋₁), level voltages for this design should be maintained with sufficient spacing; otherwise, more sophisticated gate drive designs may be needed that can limit achievable switching performance.

FIG. 1B shows an implementation of the architecture illustrated in FIG. 1A, which may be suitable for discrete supply modulation, for example.

As shown, a system 30 can comprise a multiple output supply generator 34 a supply modulator 36 and optional filter 38 and a PA 40 having an rf input 40a, an rf output 40b and a supply terminal 40c. In this example of FIG. 1B, supply generator 34 is provided as a single inductor 3-output boost converter comprising an inductor L having a first terminal coupled to a voltage supply 32 and a second terminal coupled to a node 34a. One or more switches (here three switches S₁, S₂, S₃) have a first terminal coupled to node 34a and a second terminal coupled to at least one voltage node established via capacitor stack C1, C2, C3, C4 (e.g. a plurality of capacitors C1, C2, C3, C4 serially coupled between a first voltage node and ground so as to establish a plurality of voltage nodes V₁-V₃). A fourth switch S₀ has a first terminal coupled to node 34a and a second terminal coupled to ground. In the example of FIG. 1A, the second terminal of switches S₁, S₂, S₃ are coupled to respective ones of voltage nodes V₁, V₂, V₃.

Also in the example of FIG. 1B, power supply modulator comprises a plurality of switches Sₘ₁-Sₘ₃ with a first terminal of each switch Sₘ₁-Sₘ₃ coupled to a corresponding one of voltage terminals V₁-V₃ and a second terminal of each switch Sₘ₁-Sₘ₃ coupled to a node 36a.

In the example of FIG. 1B, node 36a is coupled to supply terminal 40c of PA 40 though filter 38. In some examples, filter 38 can be provided as an LC filter comprising inductor Lf, resistor Rf and capacitors C4, C5. In other examples, node 36a may be coupled to supply terminal 40c of PA 40 through other circuitry (i.e. circuitry other than filter circuitry). In still other examples, node 36a may be directly coupled to supply terminal 40c of PA 40.

The illustrative systems illustrated in FIGS. 1A, 1B include two separate subsystems: (a) a supply generator that can synthesize multiple power supply voltages from a single input source, and possibly regulate one or more of those power supply voltages, and (b) one or more supply modulators that can each rapidly switch among the power supply voltages provided by the supply generator to provide a modulated supply voltage to a PA.

In accordance with the concepts described herein, the inventors have recognized that the manner in which these two subsystems are best implemented (or “realized”) may depend upon the power level, voltage level and application space of the rf amplifier system. The inventors have also recognized that for many mobile applications (e.g., cell phones, smart phones, personal devices and the like), it may be desirable to monolithically integrate electronic elements of both the supply generator and supply modulator on a single semiconductor die (e.g., in a CMOS process or a BCD process). The inventors have further recognized that in some cases it may be desirable to integrate electronics for the supply generator, supply modulator(s) and PAs on a single die. In other cases (especially at high power) it may be desirable to implement the subsystems with discrete components connected on one or more printed circuit boards.

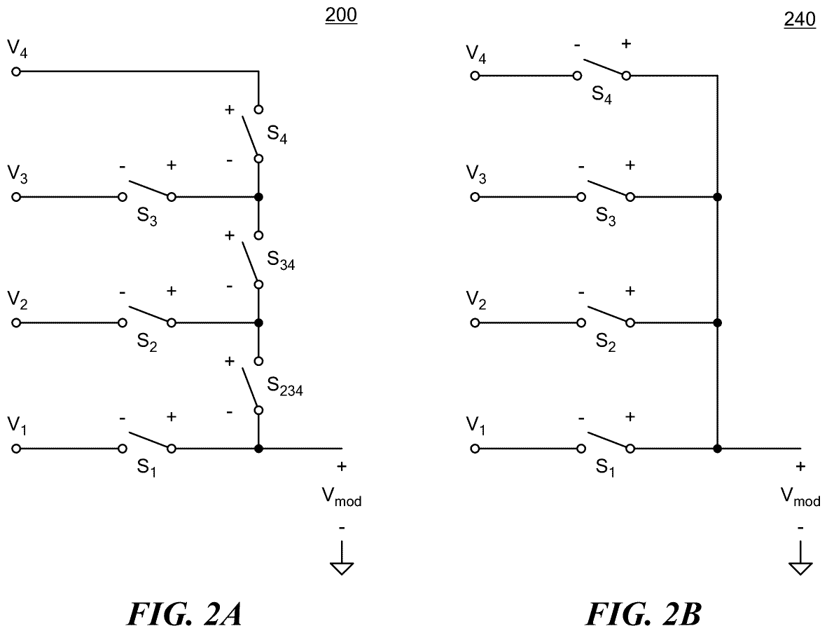

A variety of different switching circuits may be utilized to implement/realize a supply modulator subsystem. Two illustrative networks are shown in FIGS. 2A, 2B. FIG. 2A illustrates a series modulator 200 having switches S₁-S₄, S₃₄, and S₂₃₄ connected as shown. FIG. 2B illustrates a parallel modulator 240 having switches S₁-S₄ connected as shown. Additionally, filtering networks, including passive filters and/or active filters and/or additional means of regulating the voltage (e.g., including low-dropout regulator(s), LDOs) to the PA V_{supply} from the modulated voltage V_{mod}, may be utilized, as illustrated in FIG. 1.

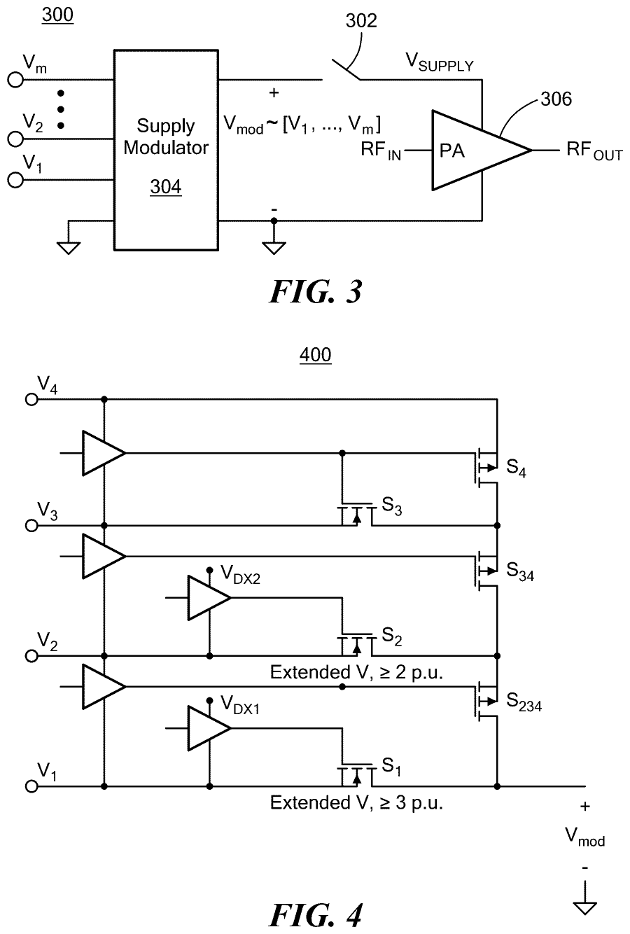

Referring now to FIG. 3, in some embodiments, the modulated power supply provided to the PA (e.g., V_{supply}) may need to be “cut off” (discharged to a zero-volt level). For example, this can be used to enable reduction of the modulator switch voltage ratings in cases when a zero output must be provided to the PA. In such cases, a circuit 300 can include a separate low-frequency turn-off switch 302 (or “disconnect switch”) coupled in series between an output of a supply modulator 304 (capable of sourcing modulator output voltages V₁, . . . , Vₘ) and a PA 306.

FIG. 4 shows an implementation of the series modulator of FIG. 2A, in a form suitable for integrated circuit fabrication and for use with ratiometric supply voltages (e.g., V₂=2V₁, V₃=3V₁, V₄=4V₁). An illustrative circuit 400 includes switches S₁, S₂, and S₃ implemented as NMOS transistors and switches S₄, S₃₄, and S₂₃₄ implemented as PMOS transistors. Circuit 400 also includes CMOS gate drivers powered differentially among levels.

Circuit 400 illustrates the impact of the supply levels on the required voltage rating of individual modulator devices; by correct selection of the level voltages, the best use of integrated CMOS processes can be made using both core devices and extended voltage devices to achieve the required voltage blocking characteristics of the modulator switch chains. Moreover, circuit 400 illustrates the use of the generated levels for gate drive of the devices (e.g., transistors). This type of drive approach can facilitate high efficiency and switching speed.

To take advantage of driving the device gates between adjacent level voltages (e.g., between Vⱼ and Vⱼ₋₁), level voltages for this design must be maintained with sufficient spacing. Otherwise, more sophisticated gate drive designs may be needed that can limit achievable switching performance. Devices, circuits and techniques described herein facilitate maintaining voltage levels that are suitable for achieving integrated circuit-based modulators and high-performance gate drives through the ability to maintain desired voltage relationships among the levels.

Supply generators can be realized through a variety of methods. For example, supply generators can be realized using multiple separate converters, multiple-output magnetic converters, multiple-output switched-capacitor converters and hybrid magnetic/switched-capacitor converters providing a ratiometric set of output voltages. A further approach is to realize a multiple-output supply generator that creates two independently controllable dc voltages (e.g., with a magnetic conversion stage) and further uses a differential capacitive energy transfer stage to realize one or more further dc supply voltages that are that ratiometrically distributed between or around the two independently controllable voltages. Each of these approaches has limitations (which some may consider substantial limitations) in terms of achievable size, cost, efficiency and/or performance (e.g., modulation bandwidth) of supply-modulated rf amplifier systems.

Use of multiple separate power converters to generate the multiple supply voltages yields a solution that is flexible, allowing each output voltage to be independently regulated to desired values independent of input voltage variations and providing the ability to continuously adjust the output voltages over time (e.g., to provide for adaptive bias of the PA). Unfortunately, this solution is inherently large and expensive, owing to the large numbers of physically large power supply components (e.g., magnetic components) required.

Single-inductor multiple-output converters, (sometimes referred to as “SIMO” converters) allow multiple output voltages to be independently regulated while only requiring a single magnetic component, somewhat mitigating the size challenge of multiple power converters. However, as SIMO designs inherently utilize time-sharing of the inductor to supply the multiple outputs, performance and efficiency can degrade and control complexity can increase with increasing numbers of outputs. This characteristic can limit the efficacy of this approach in multilevel supply modulator systems, which typically utilize between three and seven supply levels to achieve high performance (with even more levels potentially desirable in some cases).

Some types of converters, such as conventional multiple-output magnetic converters (e.g., multi-output flyback converters), multiple-output switched-capacitor converters and hybrid magnetic/switched-capacitor converters yield multiple ratiometrically related output voltages while reducing the numbers of magnetic components required as compared to using multiple independent power converters. Traditional multiple-output magnetic converters typically utilize transformers with scaled turns ratios to generate multiple (ideally) ratiometrically scaled output voltages. These designs can only usually regulate a single output, with the ratiometric relations of the other outputs approximately maintained by the transformer turns ratios (unless additional “post regulation” is provided the other outputs, such as through use of added linear regulators). The use of transformers tends to lower achievable efficiency in these designs (often to unacceptable levels), and such designs may suffer significant cross regulation among the outputs in practice (i.e., one output voltage varying depending upon the load on a different output). This results in undesirable performance in rf amplifier systems unless additional post regulation is used, which can further degrade performance.

Multiple-output switched-capacitor converter circuits can generate multiple ratiometrically related output voltages while achieving very high efficiency and small size, with the rational (ideal) ratios among output voltages determined by the circuit topology and/or switching pattern. However, with this type of circuit, the output voltages are all scaled versions of the input voltage, which does not provide a means to continuously regulate the output voltages independent of variations in the input voltage; this is a significant disadvantage in many systems.

Some limitations of these previous approaches to multiple-output supply generation can be addressed via hybrid magnetic/switched-capacitor circuits having ratiometrically scaled outputs. In these designs, a magnetic regulation stage independently regulates a single output voltage (independent of the system input voltage) with additional ratiometrically-related output voltages synthesized and enforced through the action of a switched-capacitor voltage balancer stage. For example, in an m-output supply generator, the magnetic stage may take an input voltage Vx and regulate a single output voltage V_{Y}, with the switched capacitor voltage action synthesizing (ideally) voltages k₁·V_{Y}, k₂·V_{Y}, . . . , kₘ₋₁·V_{Y}, where constants k₁, . . . , kₘ₋₁ are rational numbers determined by the circuit topology and/or switching pattern. Advantages of this approach include relatively high efficiency and small size requirements for synthesizing multiple related output voltages and relative simplicity of control.

Merits of the above design approaches notwithstanding, all designs yielding ratiometric supply generator voltage outputs have limitations (which some may consider significant limitations) for PA systems utilizing multiple level supply modulation.

One limitation of ratiometric outputs relates to the usable supply voltage ranges for available PAs. Some PAs may function well with wide supply voltage ranges of up to 4:1 or even larger (e.g., function well across a power supply voltage range from a maximum voltage of Vₘₐₓ down to a minimum voltage equal to or less than Vₘᵢₙ=Vₘₐₓ/4.) Many other PAs-including those typically used in applications such as Wi-Fi, mobile handset, and MIMO transmitters for LTE and 5G applications—can only operate over much narrower supply voltage ranges (e.g., 3:1 or even less). With ratiometric supply voltages, if the maximum voltage generated is reduced (e.g., for conditions of reduced average PA output power) then the synthesized ratiometric voltages are all reduced proportionately. This often means that one or more of the lowest synthesized voltages will become unusable for supply modulation under such conditions, as they fall below the allowed minimum PA power supply voltage. This in turn reduces the achievable PA efficiency enhancement that can be provided through supply modulation under these conditions. In many applications, it would be desirable if the power supply voltages were not maintained as a fixed set of ratios, such that all (or nearly all) of the synthesized supply voltage levels remained above the allowed minimum voltage for the PA under reduced power operation.

Another limitation of ratiometric outputs relates to how the spacing between voltages varies as the largest supply voltage synthesized is reduced. In a ratiometric-output supply generator, two adjacent voltages may be expressed as kⱼ·V_{Y} and kⱼ₋₁. V_{Y}, where k is a scaling value, j is an integer index, V is a voltage and Y is an index corresponding to the number of voltage levels, V_{Y} is the Y^{th} voltage level and where the value of V_{Y} may be scaled up or down as the average transmit power of the PA is adjusted. The difference between voltage levels may thus be expressed as (kⱼ-kⱼ₋₁). V_{Y} which scales up and down proportional to V_{Y}. As described above in conjunction with FIG. 4, this can be problematic for driving of integrated modulator switches, especially where the gate drive voltages are derived from interlevel voltages (voltage differences between levels). This can result in increased gate drive complexity in an integrated modulator, and can limit achievable switching performance of the modulator. In many applications, it would be desirable for the power supply voltages not to be maintained as a fixed set of ratios, such that the spacing between adjacent levels can be controlled independently of the maximum supply voltage synthesized.

### A Hybrid Power Supply Generator/Supply Modulator

For PA architectures using supply modulation, it may be desirable to provide a system that provides both very rapid variations in modulated power supply voltage (e.g., among multiple discrete levels) while also providing the ability to slowly adapt the voltages of the discrete levels over a desired range.

In particular, and as previously discussed, it would be useful to be able to efficiently and compactly generate a set of m discrete levels for supply to a PA, with two of the m voltage levels being independently controllable and the other m−2 voltage levels distributed in a prescribed relation to the two independently-controlled levels.

While not quite as flexible as truly independent control of all voltages, one would gain most of the practical benefits available from supply modulation (e.g., in terms of PA efficiency) while avoiding the above-described limitations associated with providing truly independent voltage level control or ratiometric levels. Such a design would provide significant advantages in combinations of size, cost, efficiency and performance as compared to existing approaches.

It would be further beneficial if one only need generate two regulated supply voltages and be able to directly provide one or more additional supply voltage levels to the PA, without the necessity of having a separate supply generator element to generate these additional levels cascaded with a supply modulator to select among the levels. Merging the functions of intermediate level generation and supply modulation can reduce the number and size of passive components (e.g., capacitors) required as well as the number, required area and loss of semiconductor elements (e.g., switches).

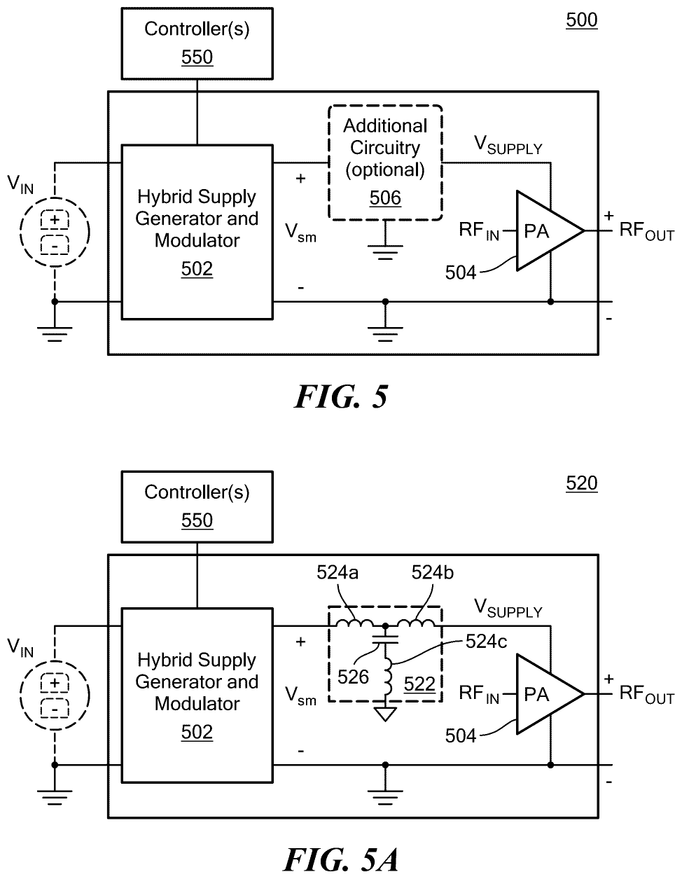

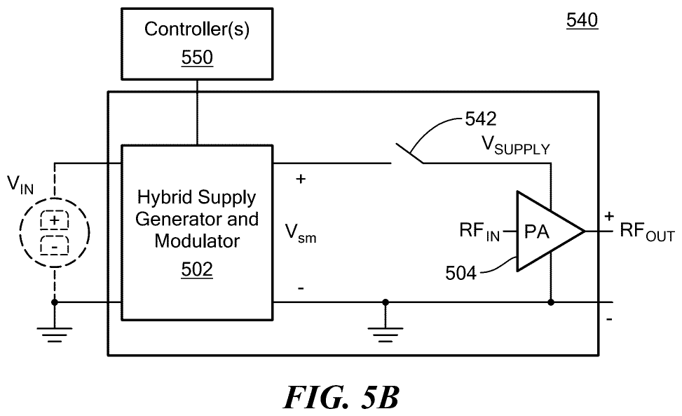

Referring now to FIG. 5, shown is a general system architecture of an rf amplifier system (or “rf module”) 500 comprising a hybrid supply generator/modulator 502 configured to generate and provide a modulated supply voltage V_{SM} to a PA 504. The hybrid supply generator/modulator 502 may comprise a hybrid magnetic/switched-capacitor power converter that can synthesize three or more discrete levels (which may be related discrete voltage levels) at its output (i.e., voltage V_{SM} may correspond to one of three or more discrete voltage levels at any instant in time). As described above, voltage V_{SM} may be based upon a pair of two independently controlled dc supply voltages that it synthesizes from an input voltage V_{IN}. In some implementations, one of the two dc supply voltages may be directly equal to voltage V_{IN}, and the second supply voltage may be independently controlled.

Of note, “hybrid magnetic/switched-capacitor converters” are a broad class of converters. Disclosed systems described as “hybrid supply generator/modulator” may be considered a specific and subtype of this broad class. Also of note, in the term, “hybrid magnetic/switched-capacitor converters,” the word “hybrid” refers to hybridization of a magnetic converter and a switched-capacitor converter together. In contrast, in the term “hybrid supply generator/modulator,” the word “hybrid” refers to hybridization of the supply generator and supply modulator.

As shown in the figure, system 500 can optionally include additional circuitry 506 coupled between an output of the hybrid supply generator/modulator 502 and the PA 504. Additional circuitry 506 may comprise, for example, a disconnect switch, filtering network(s) including passive filters and/or active filters, low-dropout regulator(s), LDO(s), and/or additional means of regulating or controlling the PA supply voltage, V_{supply}, from the modulated voltage, Vₛₘ. In some embodiments, additional circuitry 506 can have more than two terminals. For example, additional circuitry 506 can optionally be connected to ground, as shown.

System 500 can also include one or more controllers 550 to operate switches and/or other devices of hybrid supply generator/modulator 502 using control techniques described in detail below. For example, the one or more controllers 550 can implement, execute, or otherwise utilize one or more state machines described herein for modulating Vₛₘ. In some embodiments, the hybrid supply generator/modulator 502 can include a multi-output regulation stage (or “first stage”) and a differential multilevel converter (or “second stage”) and the one or more controllers 550 can include at least one controller to control the switching state of the multi-output regulation stage and at least one controller to control the switching state of the differential multilevel converter. These can be the same controller or different controllers. In some embodiments, at least one of the one or more controllers 550 may be configured to receive commands for selecting/controlling a voltage level of the modulated voltage, Vₛₘ.

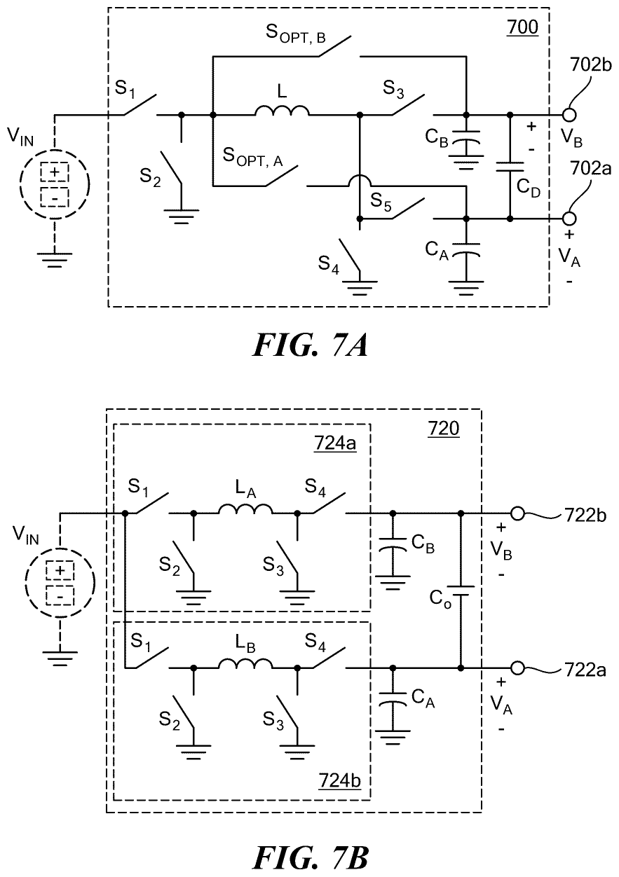

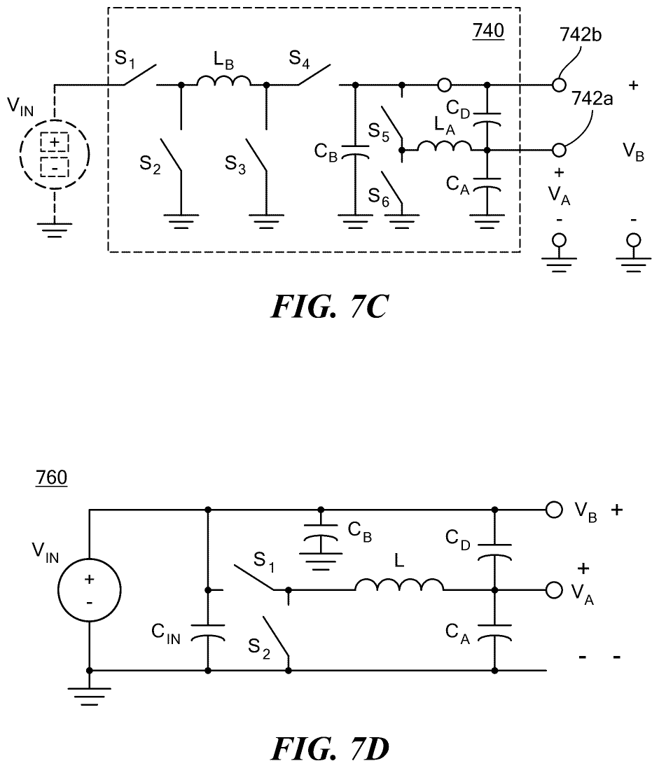

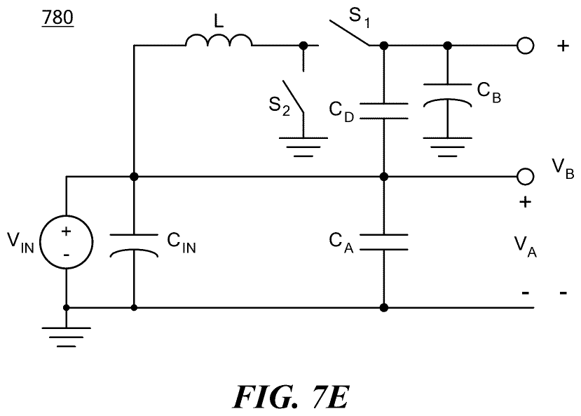

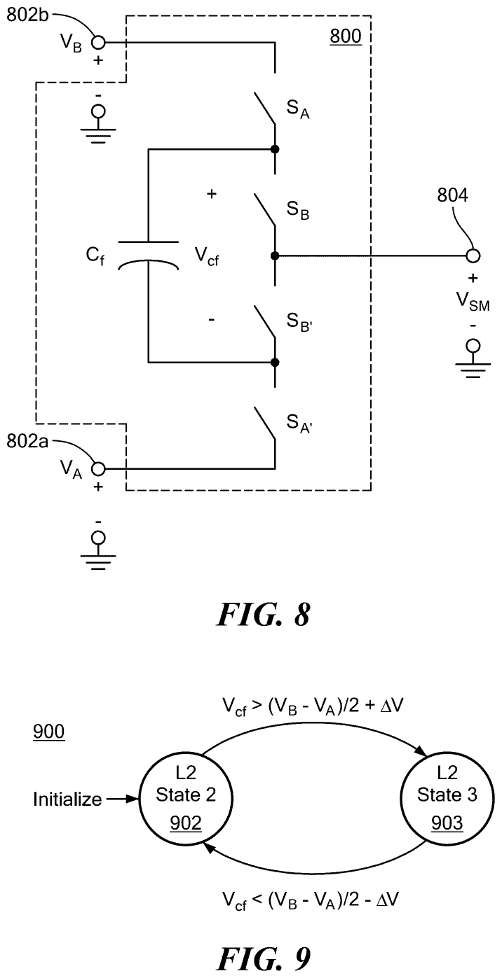

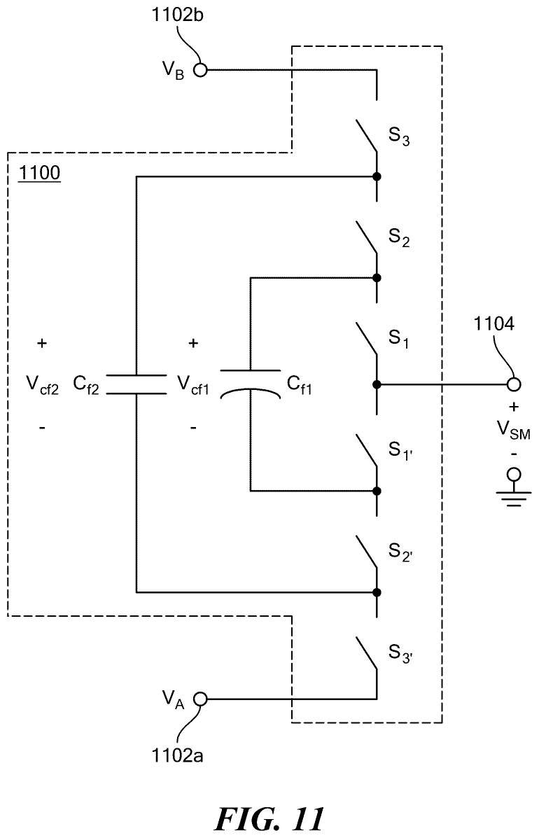

In some embodiments, the one or more controllers 550 can include a digital controller configured to provide one or more control signals to one or more hybrid supply generators/modulators. In response, the hybrid supply generators/modulators can provide variable supply voltages to one or more rf amplifiers. That is, the control signals can be used to select discrete supply voltages for the amplifiers from among multiple independent supply voltages generated by the hybrid supply generator/modulators. In more detail, the control signals may be used to directly, or indirectly, operate one or more switches within the hybrid supply generator/modulator (e.g., switches within a multi-output regulation stage such as illustrated in FIGS. 7A-E and/or switches within the differential multilevel converter such as illustrated in FIG. 8 or FIG. 11.)

FIG. 5A shows an rf amplifier system 520 similar to that of FIG. 5, wherein the additional circuitry 506 is implemented as a filter network 522. Illustrative filter network 522 includes first and second inductors 524a, 524b connected in series between an output of hybrid supply generator/modulator 502 and an input of PA 504. Filter network 522 further includes a capacitor 526 having one terminal connected between first and second inductors 524a, 524b, and a third inductor 524c connected between the other terminal of capacitor 526 and ground. Filter network 522 may sometimes be referred to as a pulse-shaping network (PSN).

The filter network 522 of FIG. 5 is merely one example and other types of filter networks may be used. For example, a reconfigurable filter may be used, whereby one or more switches are configured to change the filtering parameters (or characteristics) of filter network.

FIG. 5B shows an rf amplifier system 540 similar to that of FIG. 5, wherein the additional circuitry 506 is implemented a PA turn-off switch 542 (or “disconnect” switch). As previously discussed, in some cases, the modulated power supply provided to the PA (e.g., V_{supply}) may need to be “cut off” (discharged to a zero-volt level). For example, this can be used to enable reduction of the modulator switch voltage ratings in cases when a zero output must be provided to the PA. In such cases, a low-frequency turn-off switch 542 can be connected in series between an output of the hybrid supply generator/modulator 502 and an input of PA 504, as shown. Turn-off switch 542 can be used to selectively isolate the output of the multi-output regulation stage from the rf amplifier.

In some embodiments, rf amplifier system 540 can be part of a transceiver system having a modem among other components external to the rf amplifier system. The modem or another one of the components can directly or indirectly generate control signals to cause the turn-off switch 542 to be actuated in conjunction with enabling/disabling the rf amplifier.

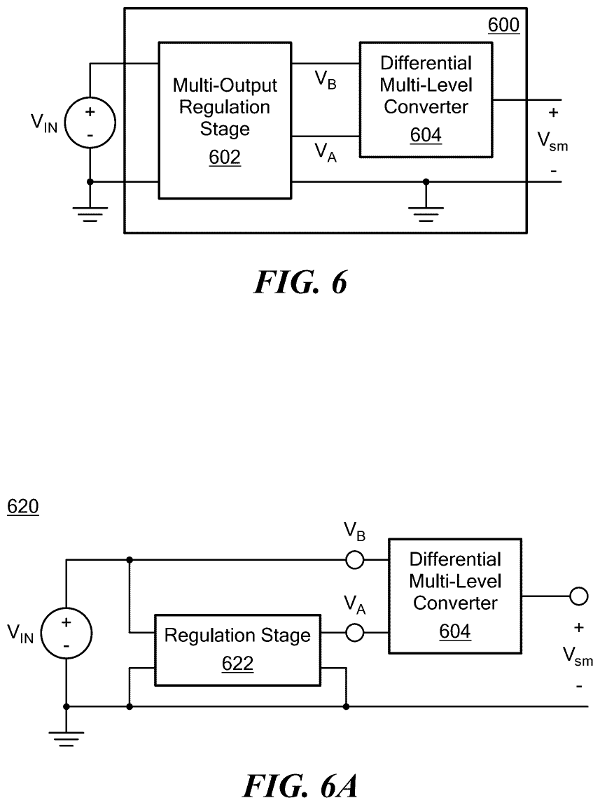

FIG. 6 shows an illustrative architecture of a hybrid supply generator/supply modulator 600, according to some embodiments. Illustrative hybrid supply generator/supply modulator 600 may be provided within the system 500 of FIG. 5. For example, modulator 600 of FIG. 6 may correspond in whole or in part to modulator 502 of FIG. 5.

Illustrative hybrid supply generator/supply modulator 600 includes a multi-output regulation stage 602 and a differentially coupled multilevel converter 604.

Multi-output regulation stage 602 is configured to receive, couple, or otherwise takes an input voltage V_{IN} and synthesizes two intermediate voltages V_{A} and V_{B}. In some embodiments, intermediate voltages V_{A} and V_{B} may be independently controllable. In some embodiments, multi-output regulation stage 602 may be provided as a magnetic or hybrid magnetic/switched-capacitor regulation stage.

Differentially coupled multilevel converter 604 has input differentially connected or otherwise coupled between intermediate voltages V_{A} and V_{B} and is configured to synthesize three or more instantaneous output voltage levels V_{SM} therefrom. In some embodiments, differentially coupled multilevel converter 604 may use switched capacitors to synthesize instantaneous levels while enabling desired voltage/charge-balance on the capacitors. Differentially coupled multilevel converter 604 may be based on a differentially connected flying-capacitor multilevel converter (FCML) or on some other capacitor-based energy-transfer topology, including those in which the charge transfer requirements prevent one or more of the synthesizable levels to be continuously provided without switching of the differentially connected multilevel converter.

Multi-output regulation stage 602 and differentially coupled multilevel converter 604 can include one or more devices (e.g., switches) configured to be controlled according to one or more control techniques described in detail below.

The multi-output regulation stage 602 and/or differential multilevel converter 604 can be controlled by one or more controllers, such as the one or more controllers 550 of FIG. 5.

FIG. 6A shows another architecture of a hybrid supply generator/supply modulator 620 wherein one of the intermediate voltages directly corresponds to the input voltage. As shown, the input voltage Vᵢₙ can be provided as input to a regulation stage 622 and also connected to provide intermediate voltage V_{B} to differential multilevel converter 604. The other intermediate voltage V_{A} provided to differential multilevel converter 604 can be generated by regulation stage 622. In other words, V_{B} can be said to bypass the regulation stage 622. Regulation stage 622 may be similar to any of the multi-output regulation stage implementations described herein or portions thereof, but adapted to have only a signal output and associated circuitry. While FIG. 6A shows an example where V_{B} corresponds to Vᵢₙ, in other examples the same general approach can be used to have V_{A} correspond to Vᵢₙ.

The multi-output regulation stage 602 and/or differential multilevel converter 604 can be controlled by one or more controllers, such as the one or more controllers 550 of FIG. 5.

Referring now to FIGS. 7A-7E, shown are implementations of a multi-output regulation stage which may be provided within the hybrid supply generator/supply modulator 600 of FIG. 6, according to embodiment of the present disclosure. For example, the multi-output regulation stage implementations of FIGS. 7A-7E may correspond, in whole or in part, to multi-output regulation stage 602 of FIG. 6. Likewise, the implementations of FIGS. 7A-7E may be used within the system 500 of FIG. 5.

FIG. 7A illustrates a multi-output regulation stage 700 comprising a two-output single-input-multiple-output (SIMO) converter based upon a 4-switch buck-boost converter, but with an additional output and switch. Multi-output regulation stage 700 has two outputs 702a and 702b (e.g., terminals) at which respective ones of synthesized voltages V_{A} and V_{B} may be provided. A first switch S₁ is connected between a voltage source, V_{IN}, and an inductive element, L. A second switch S₂ is connected at one end between S₁ and L and at the other end to ground (or, more generally, a reference voltage). A third switch S₃ is connected between L and an output 702b (providing V_{B}). A fourth switch S₄ is connected at one end between L and S₃ and at the other end to ground. A fifth switch S₅ is connected at one end between S₄, L, and S₃ and at the other end to another output 702a (providing V_{A}). Independent decoupling capacitors C_{A} and C_{B} may be connected to respective outputs 702a and 702b, as shown.

As shown, additional optional switches S_{opt.A} and S_{opt.B} may be included to enable direct energy transfer from output 702a to output 702b or vice versa. Also as shown, a differential decoupling capacitor C_{D} may be optionally included and connected across the two outputs 702a, 702b.

FIG. 7B illustrates a multi-output regulation stage 720 having two outputs 722a and 722b (e.g., terminals) at which respective ones of voltages V_{A} and V_{B} may be provided. The voltages V_{A} and V_{B} may be synthesized using separate 4-switch buck-boost converters 724a and 724b, respectively. As shown, each buck-boost converter 724a, 724b has four switches S₁-S₄ and an inductive element (L_{A} or L_{B}). Optional output decoupling capacitors C_{A}, C_{B}, and/or C_{D} may also be provided, as shown.

While the embodiment of FIG. 7B includes two buck-boost converters, depending upon voltage range requirements, two different types of converters may be used. For example, in other embodiments, one converter may be implemented as a 4-switch buck-boost, while the other converter may be implemented either as a simple buck converter (e.g., to supply the smaller of the two voltages V_{A} and V_{B}) or as a simple boost converter (to supply the larger of the two voltages V_{A} and V_{B}).

FIG. 7C illustrates a multi-output regulation stage 740 which includes a 4-switch buck-boost converter to synthesize a first output voltage V_{B} at an output 742b and includes a buck converter powered from voltage V_{B} to synthesize a second independently regulated voltage V_{A} at another output 742a, where V_{A} is less than or equal to V_{B}. In more detail, the buck-boost converter comprises switches S₁-S₄ and inductive element L_{B}, whereas the buck converter comprises switches S₅, S₆ and inductive element L_{A}. Optional output decoupling capacitors C_{A}, C_{B}, and/or C_{D} may also be provided, as shown.

It will be appreciated that other like conversion approaches can be used to synthesize two independently controllable voltages V_{A} and V_{B}. For example, the structure of FIG. 7C can be adapted such that the initial buck-boost stage is omitted, and the input (Vᵢₙ) is directly connected to capacitor C_{B}, such that voltage V_{B} equals the input voltage and voltage V_{A} is independently controllable. Like structures may be created such that voltage V_{A} equals the input voltage and voltage V_{B} is independently controllable (e.g., derived from voltage V_{A} with a boost converter).

FIG. 7D illustrates a multi-output regulation stage 760 wherein V_{B} directly corresponds to the input voltage Vᵢₙ and V_{A} is generated from Vᵢₙ using a buck converter such that V_{A}<V_{B}. The buck converter may include, for example, an input capacitor Cin, a pair of switches S₁, S₁, and an inductor L, connected as shown. Output decoupling capacitors C_{A}, C_{B}, and/or C_{D} may optionally be provided.

FIG. 7E illustrates a multi-output regulation stage 780 wherein V_{A} directly corresponds to the input voltage Vᵢₙ and V_{B} is generated from Vᵢₙ using a boost converter such that V_{A}<V_{B}. The boost converter may include, for example, a pair of switches S₁, S₁, an inductor L, and at least one of capacitors C_{B} or C_{D}, connected as shown. Decoupling capacitors C_{A} and/or CIN may optionally be provided.

Of note, whereas the hybrid supply generator/supply modulator 620 of FIG. 6A provides the input voltage as one of the intermediate voltages by bypassing the regulation stage 622, the same result can be achieved without bypassing the regulation stage, such as using the regulation stage implementation of FIG. 7D or FIG. 7E.

The various switches illustrated in FIGS. 7A-E can be controlled by one or more controllers, such as by the one or more controllers 550 of FIG. 5. For example, the one or more controllers can generate control signals that are coupled to selectively turn individual switches on or off.

FIG. 8 shows the structure of an illustrative differential multilevel converter 800 which may be the same as or similar to the differential multilevel converter described in conjunction with FIG. 6. The differential multilevel converter operates from two voltages V_{A} and V_{B} received at respective inputs 802a and 802b (e.g., terminals). The two voltages V_{A}, V_{B} may, for example, be synthesized by a multi-output regulation stage which may be the same as or similar to one of the multi-output regulation stages described above in conjunction with FIGS. 7A-7E. In some embodiments, voltage V_{B} may be controlled to be larger than voltage V_{A}. In some embodiments, V_{B} or V_{A} may correspond to an input voltage Vᵢₙ.

Differential multilevel converter 800 includes four switches S_{A}, S_{B}, S_{A′}, S_{B′} connected in series between the two inputs 802a, 802b, and a flying capacitor Cf connected at one end between S_{A} and S_{B} and at the other end between S_{A′} and S_{B}. An output 804 (e.g., a terminal) can be connected between S_{B} and S_{B′}, as shown, to provide a modulated output voltage Vₛₘ, which can be ground referenced for example. Converter 800 may optionally include a differential decoupling capacitor C_{D} (not shown) coupled between inputs 802a, 802b.

The structure of converter 800 is partially similar to that of a flying capacitor multilevel converter (FCML) with distinctions that: (1) the output 804 is taken with discrete levels instead of being filtered to provide a continuously-variable output; and (2) the dc input 802a, 802b is taken differentially between V_{A} and V_{B} rather than from an input source and common. The ground referenced output voltage Vₛₘ may thus take on discrete values distributed between voltage values V_{A} and V_{B}, with energy transferred from and between V_{A} and V_{B} and the output 804.

The switches S_{A}, S_{B}, S_{A′}, S_{B′} may be implemented in a variety of manners with some or all of the switches having unidirectional blocking capability. For example, one or all of the switches may be configured to block less than or equal to the maximum difference between V_{A} and V_{B}, but more than half the maximum difference therebetween.

In a CMOS or BCD process, one or more of the switches S_{A}, S_{B}, S_{A′}, S_{B′} may be realized as all NMOS devices or a combination of NMOS and PMOS devices, or all as PMOS devices. In some implementations one may choose to implement switches S_{A} and S_{A′} as a CMOS pair and switches S_{B} and S_{B′} as a CMOS pair. Selection of a particular implementation may be based on size/performance of the switches and/or gate drive convenience of the switches, with gate-drive levels optionally derived from V_{A} and V_{B}.

In some embodiments, the differential multilevel converter of FIG. 8 can be operated according to four (4) different switch states, providing the output voltage V_{SM} indicated in Table 1. That is, a controller (e.g., the one or more controllers 550 of FIG. 5) can be connected and configured to turn individual switches S_{A}, S_{B}, S_{A′}, S_{B′} on or off to achieve a given one of the states set forth in Table 1.

TABLE 1

| State | Switches On | V_{SM} | V_{SM≈} | Level | V_{cf} |
|---|---|---|---|---|---|
| 1 | S_{A}, S_{B} | V_{B} | V_{B} | L3 | Unchanging |
| 2 | S_{A}, S_{B′} | V_{B} − V_{cf} | (V_{A} + V_{B})/2 | L2 | Increasing |
| | | | | | (under load) |
| 3 | S_{B}, S_{A′} | V_{A} + V_{cf} | (V_{A} + V_{B})/2 | L2 | Decreasing |
| | | | | | (under load) |
| 4 | S_{B′}, S_{A′} | V_{A} | V_{A} | L1 | Unchanging |

Table 1 shows the behavior of the differential multilevel converter of FIG. 8 for different switch states. In the table, V_{cf} denotes the voltage across flying capacitor C_{f}. State one (1) passes V_{B} to V_{SM}, while state four (4) passes V_{A} to V_{SM}. State two (2) results in V_{SM}=V_{B}−V_{cf}, while state (3) results in V_{SM}=V_{A}+V_{cf}. It is appreciated herein that, with suitable switching control of the converter (i.e., appropriate selections between states two (2) and three (3)), V_{cf} will be maintained near (V_{B}−V_{A})/2, which results in both states two (2) and three (3) providing an output voltage V_{SM}=(V_{A}+V_{B})/2, as indicated in Table 1.

Controlled using the switch states of Table 1, converter 800 enables three effective levels (i.e., approximate level values) to be synthesized at its output 804: V_{A}, V_{B}, and (V_{A}+V_{B})/2. Converter 800 may thus be utilized to provide similar functionality to a 3-level supply modulator producing levels L1=V_{A}, L3=V_{B}, and L2=(V_{A}+V_{B})/2, for example.

A benefit of the design of FIG. 8 is that it combines the differential capacitive energy transfer supply generation function with the supply modulation function, reducing device area and component size as compared to using a separate differential supply generator and supply modulator.

In some embodiments, V_{cf} (the voltage across flying capacitor C_{f}) may be maintained near (V_{B}−V_{A})/2 by appropriately selecting between states two (2) and three (3) of Table 1 when seeking to synthesize an output voltage level near (V_{A}+V_{B})/2. Under a positive load current (e.g., deriving from a PA), V_{cf} will increase over time in state two (2) and will decrease over time in state three (3).

In some embodiments, when selecting which of states two (2) or three (3) to use to supply a voltage close to (V_{A}+V_{B})/2 at the modulator output (i.e., synthesizing L2), state two (2) can be selected if V_{cf} falls too far below (V_{B}−V_{A})/2 and state three (3) can be selected if V_{cf} rises too far above (V_{B}−V_{A})/2, where “too far” can be defined using one or more threshold values as described below.

In some embodiments, switching between states two (2) and three (3) can be controlled on a hysteretic basis and/or with clocked switching transitions. For example, such switching can occur instantaneously when the voltage V_{cf} exceeds an allowed voltage deviation ΔV above or below (V_{B}−V_{A})/2, or with transitions clocked, such as at a discrete supply modulation clocking rate. In some embodiments, the allowed voltage deviation ΔV value may be hardcoded in the controller, may be a programmable value of the controller, or maybe be conveyed via an external signal.

It will be appreciated that circuitry may be provided to measure/detect the voltage V_{cf} across the flying capacitor Ct. For example, a differential sensor (not shown) may be provided, with each of its two inputs connected to a different terminal of Ct and its output connected to the controller controlling the switch states.

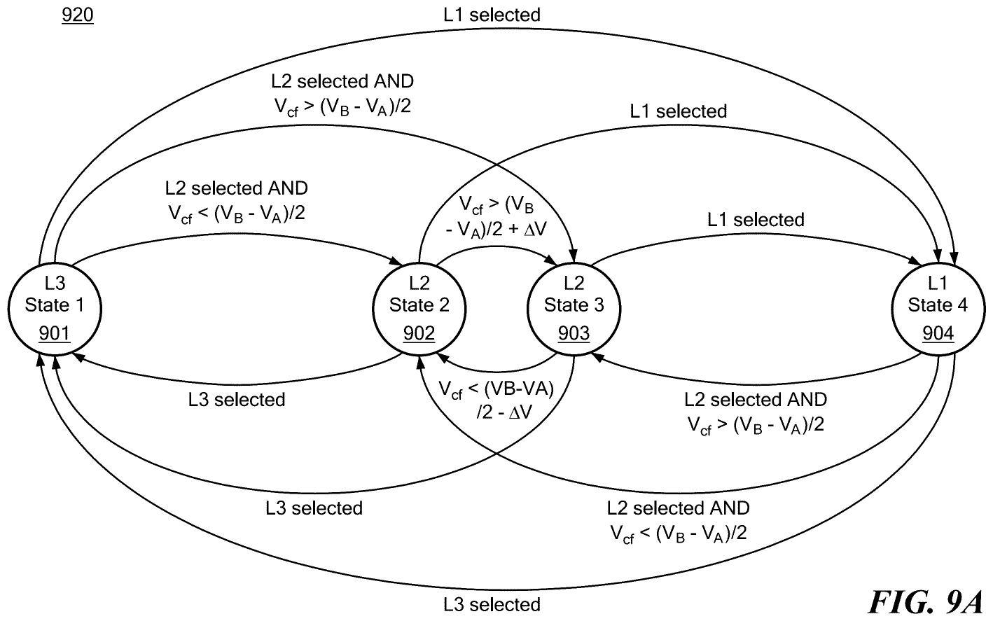

Referring now to FIG. 9, shown is an illustrative state machine 900 that may be used to control the switch state of the differential multilevel converter 800 to maintain L2 (i.e., V_{SM}=(V_{A}+V_{B})/2) by transitioning back and forth (e.g., alternating) between states two (2) and three (3). For example, when L2 is selected (e.g., when the hybrid supply generator/supply modulator is commanded to output the voltage level L2), the controller can use state machine 900 to determine whether state two (2) or three (3) is used to synthesize L2.

In the example of FIG. 9, transitions between state two 902 and state three 903 are a function of the capacitor voltage V_{cf}. In more detail, starting from state two 902, state machine 900 can transition to state three 903 when V_{cf} is greater than (V_{B}−V_{A})/2+ΔV. State machine 900 can transition back to state two 902 when V_{cf} is less than (V_{B}−V_{A})/2−ΔV.

Such state transitions can be made on either an instantaneous or clocked basis. The allowed deviation ΔV of V_{cf} from (V_{B}−V_{A})/2 determines the maximum deviation of the L2 output voltage from (V_{A}+V_{B})/2, and may be used as a fixed value or a programmable value. Reducing ΔV gives a more precise supply modulator output voltage for L2 (smaller difference between the two states synthesizing L2) but requires more frequent switching between states.

In some embodiments, state machine 900 may be re-initialized each time L2 is selected (i.e., transitioning from L1 or L3), with the initialization dependent upon voltage V_{cf}. For example, it may be desirable to initialize the state machine to state two 902 if V_{cf}<(V_{B}−V_{A})/2 and to initialize the state machine to state three 903 if V_{cf}> (V_{B}−V_{A})/2. Such a selection—or a similar one with different threshold(s)—can reduce the number of transitions required between states two (2) and three (3) to synthesize L2, and hence improve efficiency.

Turning to FIG. 9A, according to some embodiments, the illustrative state machine of FIG. 9 for maintaining L2 voltage can be integrated into a larger state machine 920 for controlling all three levels L1, L2, and L3. In addition to states 902 and 903 corresponding to L2, illustrative state machine 920 also includes state 901 corresponding to L3 and state 904 corresponding to L1.

In some cases, state machine 920 can be initialized (e.g., at startup/power up) to one of the states 901-904 based on a default voltage level programmed or hardcoded into controller, for example.

State machine 920 can transition between states 901-904 in response to level select commands, such as commands received from an external circuit or control unit. For example, as shown, state machine 920 can transition to state 904 when L1 is selected and can transition to state 901 if L3 when selected. When L2 is selected, state machine 920 can transition to either state 902 or state 903 depending on V_{cf}, the voltage across the flying capacitor.

One or more system controllers (e.g., controller(s) 550 of FIG. 5) can implement, execute, or otherwise utilize the state machine of FIG. 9 and/or FIG. 9A to control a differential multilevel converter.

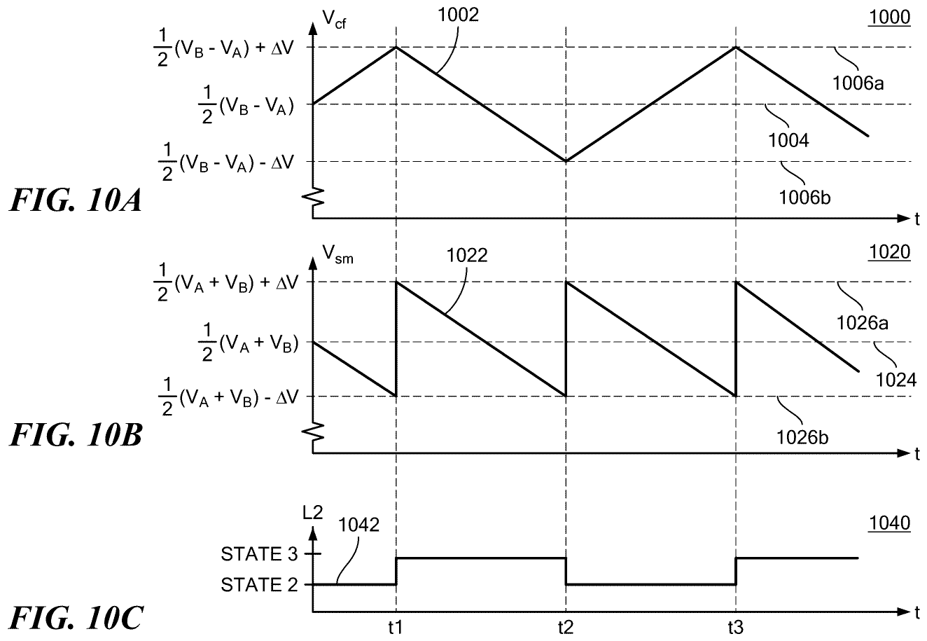

FIGS. 10A-10C illustrate voltage patterns (FIGS. 10A, 10B) and state transitions (FIG. 10C) associated with the state machine of FIG. 9 when used on an unclocked basis.

FIG. 10A shows a plot 1000 having a vertical axis corresponding to voltage and a horizontal axis corresponding to time t. A curve 1002 represents V_{cf} over time. Horizontal line 1004 indicates (V_{A}−V_{B})/2, horizontal line 1006a indicates (V_{B}−V_{A})/2+ΔV, and horizontal line 1006b indicates (V_{B}−V_{A})/2−ΔV.

FIG. 10B shows a plot 1020 having a vertical axis corresponding to voltage and a horizontal axis corresponding to time t. A curve 1022 represents Vₛₘ over time. Horizontal line 1024 indicates (V_{A}+V_{B})/2 (i.e., the effective L2 value), horizontal line 1026a indicates (V_{A}+V_{B})/2+ΔV, and horizontal line 1026b indicates (V_{A}+V_{B})/2−ΔV.

FIG. 10C shows a plot 1040 having a vertical axis corresponding to the L2 switch state (i.e., state two (2) or state three (3)) and a horizontal axis corresponding to time t. A curve 1042 indicates the L2 state, which is a function of V_{cf} (FIG. 10A). For example, at time t1, curve 1042 changes from state (2) to state (3) when curve 1002 crosses (or approaches) horizontal line 1006a. Subsequently, at time t2, curve 1042 changes from state (3) to state (2) when curve 1002 crosses (or approaches) horizontal line 1006b.

From FIGS. 10A-10C, it can be seen that the approach of transitioning between switch states as a function of V_{cf} maintains V_{cf} within a maximum voltage deviation ΔV from a center voltage (V_{B}−V_{A})/2, and maintains the supply modulator voltage Vₛₘ within a maximum voltage deviation ΔV from a center voltage (V_{B}+V_{A})/2.

L2 state selection may additionally or alternatively be done on a clocked basis. One way to do this is, for example, to use a state machine like that in FIG. 9 to select how L2 is synthesized, with the state of a state machine updated on a clock edge. The clock may be the same clock as that used to make level selections, or may be derived from it.

In some embodiments, when transitioning L2 states on a clocked basis, the manner in which L2 is synthesized on each clock cycle can be updated, choosing state two (2) if V_{cf}<(V_{B}−V_{A})/2 or state three (3) if V_{cf}> (V_{B}−V_{A})/2, optionally using a small degree of hysteresis in the comparator upon which the decision is made. For a fully clocked selection, this approach can lead to a minimum deviation in Vₛₘ from (V_{B}+V_{A})/2 for L2, at the expense of a possibly high number of transitions to do so.

Turning to FIG. 11, the general concepts, structures, and techniques described above can be extended to provide a hybrid supply generator/supply modulator having more than three (3) output levels.

FIG. 11 shows a differential multilevel converter 1100 for a hybrid supply generator/supply modulator. Converter 1100 operates from two voltages V_{A} and V_{B} received at respective inputs 1102a and 1102b, and synthesizes Vₛₘ at output 1104. In some embodiments, voltage V_{B} may be controlled to be larger than voltage V_{A}. In some embodiments, V_{B} or V_{A} may correspond to an input voltage Vᵢₙ.

Converter 1100 includes two (2) flying capacitors C_{f1}, C_{f2} and three (3) complementary switch pairs S₁/S_{1′}, S₂/S₂, and S₃/S_{3′}. The switch pairs can be operated (e.g., by a controller) according to eight (8) different switch states to provide four (4) effective output levels (Vₛₘ).

A voltage V_{cf1} across first flying capacitors C_{f1} can be controlled to be near (V_{B}−V_{A})/3 and a voltage V_{cf2} across second flying capacitors C_{f2} can be controlled to be near 2(V_{B}−V_{A})/3, enabling one to synthesize four effective output levels:

$$\begin{matrix}\begin{matrix}\begin{matrix}L 1 = {V}_{A} ; \\ L 2 = {V}_{B} - 2 ( {V}_{B} - {V}_{A} ) / 3 \approx {V}_{A} + ( {V}_{B} - {V}_{A )} / 3 ;\end{matrix} \\ L 3 = {V}_{B} - ( {V}_{B} - {V}_{A} ) / 3 \approx {V}_{A} + 2 ( {V}_{B} - {V}_{A )} / 3 ; and\end{matrix} \\ L 4 = {V}_{B} .\end{matrix}$$

There is thus an evenly spaced distribution of effective output levels between V_{A} and V_{B}.

In some embodiments, switches S₁, S₁, S₂, S_{2′}, S₃, S₃ may be selected to have a voltage rating of more than ⅓ the maximum difference between V_{B} and V_{A}, but need not be rated for more than the maximum difference between V_{B} and V_{A}. Again, gate drive sources for the switches may be derived from input voltages V_{A}, V_{B} and/or flying capacitor voltages V_{cf1}, V_{cf2}.

Table 2 shows the behavior of the differential multilevel converter 1100 of FIG. 11 for eight (8) different switch states.

TABLE 2

| State | Switches On | V_{SM} | V_{SM≈} | Level | V_{cf1} | V_{cf2} |
|---|---|---|---|---|---|---|
| 1 | S_{1′}, S_{2′}, S_{3′} | V_{A} | V_{A} | L1 | Unchanging | Unchanging |
| 2 | S_{1′}, S_{2′}, S₃ | V_{B} − V_{cf2} | V_{B} − 2(V_{B} − V_{A})/3 | L2 | Unchanging | Increasing |
| 3 | S_{1′}, S₂, S_{3′} | V_{A} + V_{cf2} − V_{cf1} | V_{B} − 2(V_{B} − V_{A})/3 | L2 | Increasing | Decreasing |
| 4 | S_{1′}, S₂, S₃ | V_{B} − V_{cf1} | V_{B} − (V_{B} − V_{A})/3 | L3 | Increasing | Unchanging |
| 5 | S₁, S_{2′}, S_{3′} | V_{A} + V_{cf1} | V_{B} − 2(V_{B} − V_{A})/3 | L2 | Decreasing | Unchanging |
| 6 | S₁, S_{2′}, S₃ | V_{B} − V_{cf2} + V_{cf1} | V_{B} − (V_{B} − V_{A})/3 | L3 | Decreasing | Increasing |
| 7 | S₁, S₂, S_{3′} | V_{A} + V_{cf2} | V_{B} − (V_{B} − V_{A})/3 | L3 | Unchanging | Decreasing |
| 8 | S₁, S₂, S₃ | V_{B} | V_{B} | L4 | Unchanging | Unchanging |

As can be seen from Table 2, there is one way to synthesize L2 (i.e., state one (1)), one way to synthesize L4 (i.e., state eight (8)), and three ways to synthesize each of the two intermediate effective output levels L2 and L3. In particular, L2 may be synthesized with states two (2), three (3), and five (5) while L3 may be synthesized with states four (4), six (6), and seven (7).

The states synthesizing each of the two intermediate effective levels each have different effects on the charging and discharging of C_{f1} and C_{f2}. (i.e., V_{cf1} or V_{cf2} increasing or decreasing under load). By dynamically choosing which state is used to synthesize a desired intermediate output level, the capacitor voltages V_{ON} and V_{cf2} can be maintained each near their target voltages of (V_{B}−V_{A})/3 and 2(V_{B}−V_{A})/3. These control selections can be done through a variety of means including through use of one or more appropriate state machines. For example, a control scheme/state machine can be selected to have V_{cf1} to be maintained within a voltage ΔV₁ of the target voltage (V_{B}−V_{A})/3 and V_{cf2} to be maintained within a voltage ΔV₂ of the target voltage 2(V_{B}−V_{A})/3. The values ΔV₁ and ΔV₂ may be hardcoded in the controller, may be programmable values of the controller, or maybe be conveyed via one or more external signals.

It will be appreciated that circuitry may be provided to measure/detect the voltage Ver across flying capacitor C_{f1} and the voltage V_{cf2} across flying capacitor C_{f2}. For example, two differential sensors (not shown) may be provided, one having its inputs connected across C_{f1} and the other having its inputs connected across C_{f2}. The outputs of both differential sensors can be connected to the controller controlling the switch states.

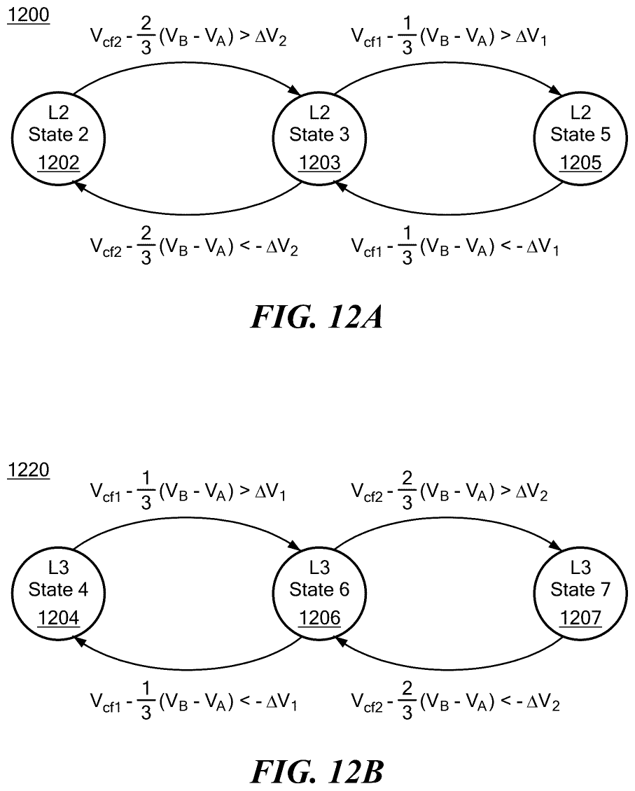

FIGS. 12A and 12B show state machines that can be used to control the switch state of the differential multilevel converter 1100 of FIG. 11.

FIG. 12A shows a state machine 1200 that may be used to control the switch state of the converter 1100 to maintain L2 by transitioning between state two 1202, state three 1203, and state five 1205 as a function of V_{cf} or V_{cf2}. For example, when L2 is selected (e.g., when the hybrid supply generator/supply modulator is commanded to output the voltage level L2), the controller can use state machine 1200 to determine whether state two (2), three (3), or five (5) is used to synthesize L2.

FIG. 12B shows a state machine 1220 that may be used to control the switch state of the converter 1100 to maintain L3 by transitioning between state four 1204, state six 1206, and state seven 1207 as a function of V_{cf1} or V_{cf2}. For example, when L3 is selected, the controller can use state machine 1220 to determine whether state four (4), six (6), or seven (7) is used to synthesize L3.

The illustrative state machines of FIGS. 12A, 12B will select which states to use to synthesize the intermediate output levels within the desired tolerances. Again, the state machines can be implemented on a clocked or unclocked basis. It will be apparent that there is adequate control authority in the proposed system to select states to both synthesize the desired output levels and maintain the flying capacitor voltages in an acceptable range; many other means can likewise be realized to do so.

The illustrative state machines of FIGS. 12A, 12B can be integrated into a larger state machine with eight distinct states as in Table 2 for controlling all four levels L1-L4, with transitions occurring in response to level select commands (similar to the state machine described above in the context of FIG. 9A for a 3-level converter).

After reading the disclosure provided herein, those of ordinary skill in the art will appreciate that hybrid supply generator/supply modulator designs having more flying capacitors and more effective output levels can be synthesized by direct extension of the 3-level design of FIG. 8 and the 4-level design of FIG. 11.

In general, designs providing N effective output levels may utilize N−2 flying capacitors and N−1 complementary switch pairs (yielding up to 2(N−1) switch states that may be used for level synthesis).

It will be appreciated that additional circuitry may be used to pre-charge the flying capacitors (e.g., C_{f1} in FIG. 8 or C_{f1} and C_{f2} in FIG. 11) to desired levels before modulation starts.

In some embodiments, additional circuitry may also be provided to maintain the flying capacitor voltages to within a desired range (e.g., close to their respective target voltages) during time periods when the synthesized output levels do not provide charging/discharging control of the capacitor voltage(s), when the system is not operating (e.g., in standby mode or in startup), and/or when the voltage levels V_{A}, V_{B}, or their references are adjusted. Such circuitry might comprise linear circuits (e.g., current sources, linear regulators, etc.) implemented in the integrated circuit.

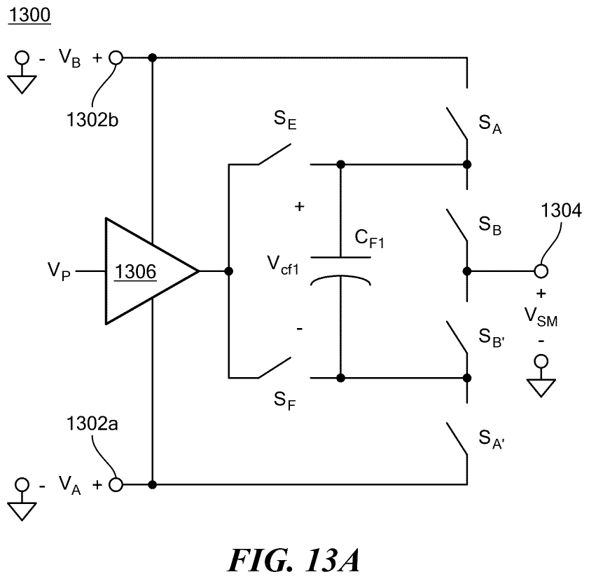

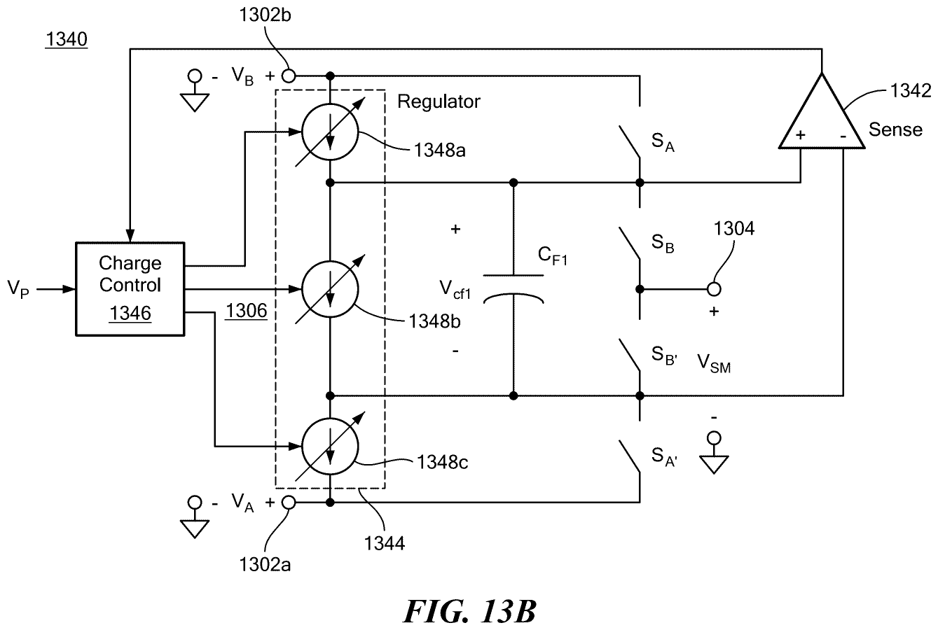

FIG. 13A shows an example of a differential multilevel converter 1300 with one flying capacitor Ct and circuitry for regulating or controlling charge thereon, according to some embodiments.

Converter 1300 operates from two voltages V_{A} and V_{B} received at inputs 1302a and 1302b, respectively. The two voltages may, for example, be synthesized by a multi-output regulation stage which may be the same as or similar to one of the multi-output regulation stages described above in conjunction with FIGS. 7A-7E. In some embodiments, voltage V_{B} may be controlled to be larger than voltage V_{A}. An output 1304 provides a modulated output voltage Vₛₘ, which can be ground referenced.

As shown, the differential multilevel converter circuit includes a set of four switches S_{A}, S_{B}, S_{A′}, S_{B′} connected in series between inputs 1302a, 1302b, a flying capacitor C_{f1} having a first terminal connected between switches S_{A} and S_{B}, and a second terminal connected between switches S_{A} and S_{B′}.

To regulate charge on the capacitor Ch, the converter 1300 further includes charge regulation circuitry (sometimes referred to as “pre-charge” or “charge holding” circuitry). In the example of FIG. 13A, the charge regulation circuitry includes a regulator 1306 (e.g., a linear regulator) receiving a reference voltage V_{P}, a fifth switch S_{E} connected between an output of regulator 1306 and a first terminal of flying capacitor Ch, and a sixth switch S_{F} connected between the output of regulator 1306 and a second terminal of flying capacitor CH. The linear regulator may be supplied differentially between V_{A} and V_{B} is designed to source and/or sink current to make its output voltage close to the reference voltage V_{P}. The reference voltage V_{P} may be selected based on the levels V_{A} and V_{B}. To regulate charge on the flying capacitor in a three-level system, reference voltage V_{P} may be selected to be half-way in between V_{A} and V_{B} such that the linear regulator seeks to charge vcf1 towards half of (V_{B}−V_{A}). Alternatively, it may be dynamically programmable (e.g., from external circuitry). In a four-level system, one may have a charge control circuit for each of the flying capacitors, with reference voltages selected to charge the capacitor voltages towards (V_{B}−V_{A})/3 and 2(V_{B}−V_{A})/3, respectively.

Converter 1300 provides a ground referenced output voltage Vₛₘ taken between switches S_{B} and S_{B}, as shown. The output voltage Vₛₘ may take on discrete values distributed between voltage values V_{A} and V_{B}, with energy transferred from and between V_{A} and V_{B} and the output.

The switches in FIG. 13A may be implemented in a variety of manners including but not limited to the various switch implementations described above with FIG. 8.

The regulator 1306 and switches S_{E}, S_{F} may be used to regulate the flying capacitor voltage Ven to within a desired range (e.g., close to reference voltage Vₚ) during time periods when the synthesized output levels do not provide charging/discharging control of the capacitor voltage(s), when the system is not operating (e.g., in standby mode or in startup), and/or when the voltage levels V_{A}, V_{B} or their references are adjusted.

In a state where switch S_{A} is held on, switch S_{F} may be turned on and the regulator 1306 can sink or source current through C_{f1} such that the voltage on C_{F} is maintained close to a desired reference voltage Vₚ. Likewise, in a state where switch S_{A′} is held on, switch S_{E} may be turned on and regulator 1306 can sink or source current through C_{f1} such that the voltage on C_{f1} is maintained close to the desired reference voltage Vₚ.

The reference voltage V_{P} can be related to the intermediate voltages V_{A}, V_{B}. For example, V_{P} can be at the midpoint between V_{A} and V_{B}, that is, V_{P}=(V_{B}+V_{A})/2. One could optionally create reference voltage V_{P} through a voltage divider between V_{A} and V_{B}. Alternatively, the reference voltage V_{P} may be provided externally in either analog or digital form.

Regulator 1306 may be configured to drive the voltage across C_{f1} to match reference voltage V_{P} or may be configured to act to drive the voltage across C_{f1} towards V_{P} only when the difference between V_{P} and V_{cf1} exceeds a threshold value ΔVₚ>0. In some embodiments, the threshold ΔV_{P} may be selected to greater than the voltage ΔV used for selecting the switch state to synthesize the output voltage level near (V_{B}+V_{A})/2.

In some embodiments, regulator 1306 (e.g., a linear regulator) may be configured to source or sink current if V_{ON} is greater than a magnitude ΔVₚ away from Vₚ. This can include a hysteretic comparison. In some examples, one comparator with hysteresis may be used. In other examples, two comparators may be used: a first comparator to detect when V_{cf} is greater than Vₚ+ΔVₚ and a second comparator to detect when V_{cf} is less than Vₚ−ΔVₚ. If the first comparator is activated, regulator 1306 may be activated to drive V_{cf} down. If the second comparator is activated, regulator 1306 may be activated to drive V_{cf} up. When the voltage is within Vₚ−ΔVₚ<V_{cf}<Vₚ+ΔVₚ, the regulator may not act.

In some embodiments, charge regulation circuitry (e.g., regulator 1306 and switches S_{E}, S_{F}) may be selectively activated and deactivated based on operating mode, modulator state, duration of a particular modulator state, etc. For example, charge regulation circuitry be selectively activated during modes such as startup and standby, or during particular states of the modulator (such as when switch S_{A} or S_{A′} is active) or when particular states of the modulator are held for more than a certain duration, or when voltages V_{A} and V_{B} are being adjusted.

FIG. 13B shows another example of a differential multilevel converter 1340 with one flying capacitor and circuitry for regulating or controlling charge thereon, according to some embodiments. Similar to the converters of FIGS. 8 and 13A, converter 1340 of FIG. 13B includes a set of four switches S_{A}, S_{B}, S_{A′}, S_{B′} connected in series between inputs 1302a, 1302b, a flying capacitor C_{f1} having a first terminal connected between switches S_{A} and S_{B}, and a second terminal connected between switches S_{A′} and S_{B′}.

Additionally, converter 1340 of FIG. 13B includes a differential sensor 1342, a regulator 1344, and a charge control circuit 1346, which may collectively be referred to as the “charge regulation circuitry.” Differential sensor 1342 has inputs connected to opposite terminals of CH to detect the voltage Ven across Ch, and an output connected as input to charge control circuit 1346. Regulator 1344 can include controllable source elements 1348a-1348c (e.g., controllable current sources) that can charge and discharge capacitor Ch. Charge control circuit 1346 receives a reference input Vₚ (e.g., a reference voltage) and the output of differential sensor 1342 and is configured to control the regulator and, more particularly, to control individual source elements 1348a-1348c of regulator 1344.

In some embodiments, charge control circuit 1346 may be configured to charge or discharge C_{cf1} if its voltage V_{ON} is more than some magnitude ΔVₚ away from Vₚ. In some examples, this may be done using two comparators: a first comparator to detect when V_{ON} is more than Vₚ+ΔVₚ and a second comparator to detect when V_{cf} is less than Vₚ−ΔVₚ. If the first comparator is activated, then middle current source 1348b can be activated/turned up to drive V_{cf1} down. If the second comparator is activated, current sources 1348a and 1348c can be activated to drive V_{cf1} up. When the voltage is within Vₚ−ΔVₚ<V_{cf}<Vₚ+ΔVₚ, all current sources 1348a-c can be turned off.

In some embodiments, reference input Vₚ can be related to the intermediate voltages V_{A}, V_{B} such as discussed above for FIG. 13A.

In some embodiments, current sources 1348a-c of FIG. 13B may be controlled to regulate the voltage at each terminal of the capacitor in response to V_{A} target voltage, V_{B} target voltage, system operating mode, and/or other conditions.

Similar to the charge regulation circuitry discussed above with FIG. 13A, the charge regulation circuitry of FIG. 13B can drive the voltage across C_{f1} to match reference input Vₚ or may be configured to act to drive the voltage across C_{f1} towards V_{P} only when the difference between Vₚ and V_{ON} exceeds a threshold value ΔVₚ. In some embodiments, the threshold ΔVₚ may be selected to greater than the voltage ΔV used for selecting the switch state to synthesize the output voltage level near (V_{B}+V_{A})/2.

Also as discussed above with FIG. 13A, the charge regulation circuitry of FIG. 13B may be selectively activated and deactivated based on operating mode, modulator state, duration of a particular modulator state, etc.

FIGS. 13A and 13B illustrate charge regulation used with a differential multilevel converter 1340 having a single flying capacitor, such as may be used to provide three effective output levels. For converters with greater numbers of flying capacitors (e.g., the converter of FIG. 11 configured to provide four effective output levels), the general structures and techniques shown and described with FIGS. 13A and 13B may be extended to control charge on each of the flying capacitors. For example, using the approach of FIG. 13A, a separate linear regulator 1306 and pair of switches S_{E}, S_{F} may be provided for each flying capacitor. As another example, using the approach of FIG. 13B, a separate charge control circuit 1346 and set of controllable source elements 1348a-1348c may be provided for each flying capacitor.

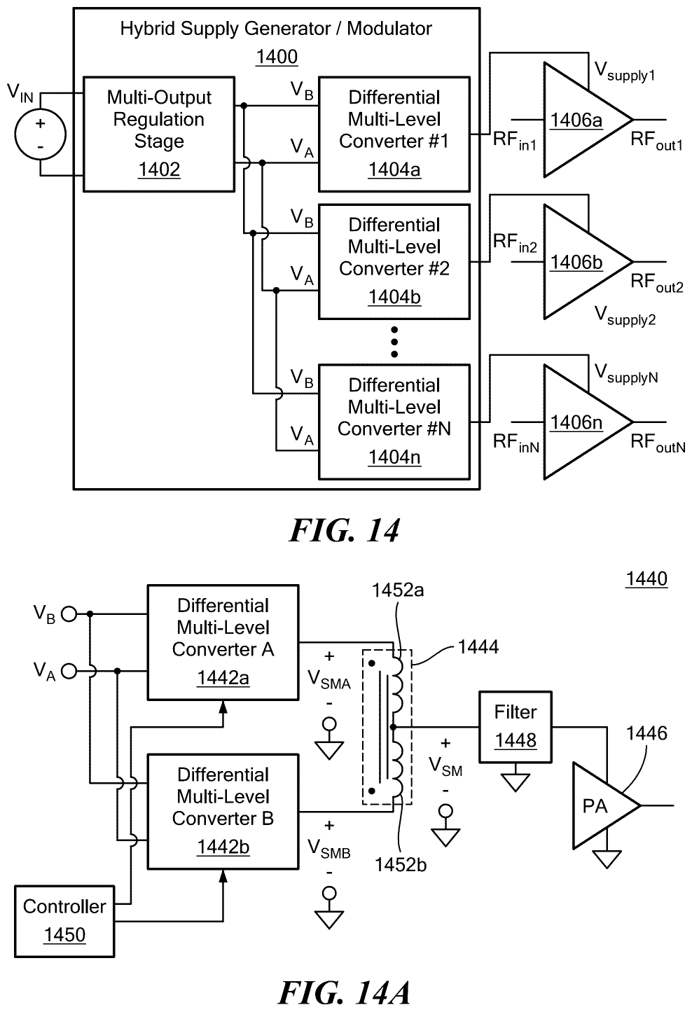

Turning to FIG. 14, according to embodiments of the present disclosure, a hybrid supply generator/supply modulator can have multiple outputs to supply one or more power amplifiers (e.g., with different voltages).

Illustrative hybrid supply generator/supply modulator 1400 includes a single multi-output regulation stage 1402 and a plurality of differentially-coupled multilevel converters 1404a, 1404b, . . . , 1404n. Multi-output regulation stage 1402 receives input voltage V_{IN} and synthesizes two intermediate voltages V_{A} and V_{B} which may be independently controllable. Each of the differentially-coupled multilevel converters 1404a-n may receive the intermediate voltages V_{A} and V_{B} and be configured to synthesis one of three or more instantaneous output voltage levels, which voltage levels may be used to supply a corresponding one of a plurality of PAs 1406a-n.

In some embodiments, the differentially-coupled multilevel converters 1404a-n may directly provide supply voltages V_{supply1 . . . N} to the PAs 1406a-n, as shown. In other embodiments, the outputs of the differentially-coupled multilevel converters 1404a-n may be filtered/regulated using additional circuitry to provide the plurality of PA supply voltages V_{supply1 . . . N}. Examples of such additional circuitry are described above in the context of FIGS. 5, 5A, and 5B. In any case, it will be appreciated that different ones of the PA supply voltages V_{supply1 . . . N} may be independently controllable using the system architecture of FIG. 14.

Multi-output regulation stage 1402 may be the same as or similar to any of the multi-output regulation stage embodiments disclosed herein. Likewise, a given one of the differentially-coupled multilevel converters 1404a-n may be the same as or similar to that any of the differentially-coupled multilevel converter embodiments disclosed herein.

In some embodiments, multi-output regulation stage 1402 can be realized on an IC. In some embodiments, differential multilevel converters 1404-n can be realized on one or more ICs. In some embodiments, the multi-output regulation stage 1402 IC can be different from the differential multilevel converters 1404-n IC(s). In some embodiments, multi-output regulation stage 1402 and one or more differential multilevel converters 1404-n can be realized on the same IC.

Turning to FIG. 14A, in some embodiments, the outputs of two or more differential multilevel converters can be combined (e.g., using coupled magnetics) to supply a single PA. Illustrative system 1440 includes differential multilevel converters 1442a, 1442b both configured to receive the same intermediate voltages V_{A} and V_{B} and to provide a respective modulated voltage V_{SMA} and V_{SMB}. System 1440 further includes a combiner circuit 1444 configured to combine the modulated voltages V_{SMA}, V_{SMB} into a combined modulated voltage V_{SM}, which is used to supply a PA 1446. For example, V_{SM} may be coupled directly or indirectly to a bias port of PA 1446.

System 1440 can optionally include a filter circuit 1448 or other additional circuitry coupled between combiner circuit 1444 and PA 1446, as shown. For example, filter circuit 1448 can be configured to filter to smooth the transitions of supply voltage provided to PA 1446.

A controller 1450 can be coupled to control (e.g., independently control) switching states of the differential multilevel converters 1442a and 1442b. In some embodiments, controller 1450 may be provided as part of a hybrid supply generator/modulator that also includes differential multilevel converters 1442a, 1442b. For example, controller 145 may be implemented on the same IC as converters 1442a, 1442b.

It should also be appreciated that combiner circuit 1444 may be provided as any means capable of combing two or more modulated power supply output signals provided thereto so as to provide a combined modulated signal appropriate for use in an application of interest. Examples of such combining means are provided below. After reading the disclosure provided herein, one of ordinary skill in the art will appreciate how to select or design a means for combining appropriate for use in a particular application.

In the illustrative embodiment of FIG. 14A, combiner circuit 1444 is provided as a coupled magnetic structure having a high coupling (e.g., coupling coefficient in the range or about 0.5 or greater or in some applications, it may be desirable or necessary to utilize a coupling coefficient in the range of about 0.9 or greater) between windings 1452a, 1452b (e.g. an interphase transformer combiner). In this embodiment, output, V_{SM}, of combiner circuit 1444 is a linear combination of the inputs from the individual converters 1442a, 1442b.

Combiner circuit 1444 is not limited to interphase transformer combiners. It may comprise, for example, uncoupled magnetics (e.g., separate inductors or uncoupled windings on a single core structure), a transmission-line transformer combiner, a lumped or distributed GF combiner or hybrid circuit, or another three-port lumped or distributed passive network.

Also, while two converters 1442a, 1442b and a two-way combiner are shown in the example of FIG. 14A, a system may generally include M modulators and an M-way combiner. This may allow for increasingly high performance (e.g., reduced content of undesired frequencies for a given desired frequency content) as M is increased.

Two or more multilevel converters may be used together to provide a single output V_{SM}. One such technique that can be used with illustrative system 1440 is so-called “split pulse transitions” (SPT). With SPT, controller 1450 can receive a controller input signal indicating a voltage level desired at the combiner output V_{SM}, and produce outputs which are, in turn, inputs to the differential multi-level converters. Controller 1450 can independently command the output voltage level V_{SMA} and V_{SMB} of two multilevel converters 1442 and, thus, V_{SM}, based on the desired voltage level indicated by the controller input signal. One skilled in the art may appreciate that more than two differential multilevel converters may be combined in similar fashion to implement SPT.

In some embodiments, controller 1450 may be configured to delay the output signal for converter 1442b or converter 1442a such that a transition observed at V_{SMA} occurs after the same transition occurred at V_{SMB}. This delay may be referred to as a “split pulse transition delay” or “SPT delay.” In this case, voltages V_{SMA} and V_{SMB} may be unequal for a period of time corresponding to the SPT delay. Controller 1450 can apply the SPT delay to either converter 1442b or converter 1442a according to a state machine implemented as part of the controller. Which multi-level converter 1442b, 1442a input receives the delay may change as frequently as every transition of the desired voltage level indicated by the controller input signal.

In some embodiments, when the SPT delay is configured to a value greater than zero, the overall transition of V_{SM} from a first level to a second level will be comprised of three voltage levels spanning three portions. During the first portion of the overall transition at V_{SM}, both V_{SMA} and V_{SMB} have the same output voltage such that Vₛₘ is equal to V_{SMA} and V_{SMB}. During the second period the controller commands the desired transition for multilevel converter 1442a, such that V_{SMA} transitions to the second voltage level, but 1442b output V_{SMB} remains at the original level. During this portion current flows between the outputs of 1442a and 1442b through combiner 1444. Vₛₘ takes on a value between V_{SMA} and V_{SMB} proportional to the ratio of the number of turns on winding 1452a to the number of turns on winding 1452b. Assuming an equal number of turns, the voltage Vₛₘ will be (V_{SMA}-V_{SMB})/2+V_{SMA} during this second period. The controller may delay the command for 1442a or 1442b according to an internal state machine. During the final period the controller commands the desired transition for multilevel converter 1442b, such that the output of 1442a and 1442b are again equal, and Vₛₘ will be equal to V_{SMA} and V_{SMB}.

SPT has the effect of changing transition shape while retaining high efficiency of the hybrid supply modulator/generator. Without SPT, the voltage V_{SM} changes quickly from a first voltage level to a second voltage level. The sample SPT implementation above reduces dv/dt (voltage slew rate) of Vₛₘ during the transition: V_{SM} starts at the first voltage level, moves to a voltage level between the first and second voltage levels during the SPT delay time, and then moves to the second voltage level after the SPT delay time. The SPT delay duration between 1442a and 1442b changes frequency content of the output V_{SM}, and may be configured to optimize the time domain shape and frequency domain content of V_{SM}. A transceiver may command the controller 1450 to adjust SPT delay time to optimize RF performance for challenging operating conditions (e.g. high- or low-bandwidth transmission, stringent linearity or emissions requirements).

While FIG. 14A shows an example of two differential multilevel converters 1442b, 442a and the preceding discussion explains how one of the converters can be delayed relative to the other, the general concepts and techniques described may be applicable to other numbers of converters. For example, a hybrid supply generator/modulator can have at least three differential multilevel converters, and the controller can be applied two or more different delays to the at least three differential multilevel converters.

In some embodiments, a system disclosed herein (e.g., system of FIG. 14A) can utilize one or more control techniques described in U.S. Pat. No. 11,909,358, issued on Feb. 20, 2024, and entitled “Multilevel Amplifier Systems and Related Techniques,” which patent is incorporate by reference in its entirety.

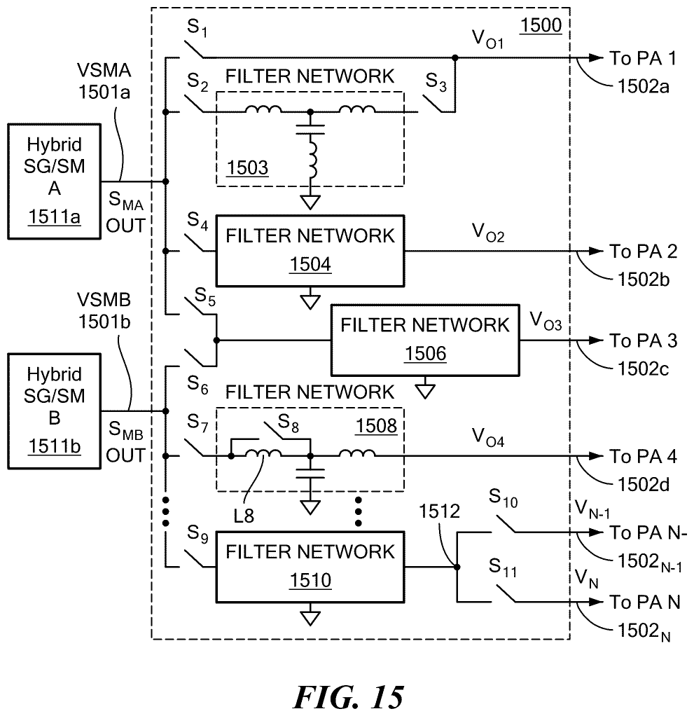

Turning to FIG. 15, as previously discussed, an RF power amplifier system may include a controller (e.g., one of controllers 550 of FIG. 5) configured to provide one or more control signals to one or more hybrid supply generators/modulators. In some embodiments, the variable supply voltages (or “supply bias voltages”) may be provided in the form of pulses with each pulse having one of a discrete number of voltage levels. That is, the hybrid supply generators/modulators can each provide one of a plurality of discrete supply voltages to the supply/bias terminal of a corresponding rf amplifier (or in some cases, to multiple rf amplifiers). Such discrete voltage supply levels may be predetermined or may be adapted over time based upon required average transmit power levels or other factors.

Transitions between pulses of different voltage levels (i.e., transitions from one voltage level to another) can give rise to undesired frequency components in the varying supply voltage signals. In some embodiments, such variable supply voltages can be provided to the supply/bias terminal of the amplifier through one or more pulse shaping networks (PSNs). A PSN functions to filter out or otherwise remove undesirable frequency components in a supply voltage signal (i.e., the PSN filters or shapes the trajectory of the supply voltage signal). Thus, a filtered supply voltage signal is provided to the supply terminal of the rf amplifier. In the context of FIG. 5, PSNs may correspond to, or form a part of, the additional circuitry 506, for example. In some cases, the supply generator, supply modulator, and PSN may be provided as a power management integrated circuit (PMIC).

FIG. 15 shows an example of a switching network having one or more PSNs and being coupled to one or more hybrid supply generator/modulators. Illustrative switching network 1500 has one or more inputs each of which may be coupled to one or more hybrid supply generator/modulators with two hybrid supply generator/modulators 1511a, 1511b show in this example. Alternatively or additionally, rather than outputs separate hybrid supply generators/modulators 1511a and 1511b, signals 1501a and 1501b (and so forth) may represent multiple outputs of a single hybrid supply generator/supply modulator (e.g., the differential multilevel converter outputs 1404a and 1404b of hybrid supply generator/modulator 1400 in FIG. 14), or as combinations of outputs of a single multi-output hybrid supply generator/supply modulator and one or more other hybrid supply generator/supply modulator(s).

In some implementations, the switching network 1500 may be coupled in a cascaded configuration with the hybrid supply generator/modulators 1511a, 1511b. In this example embodiment, switching network 1500 comprises two inputs 1501a, 1501b coupled to outputs of respective ones of hybrid supply generator/modulators 1511a, 1511b. Hybrid supply generator/modulators (A and B) respectively supply modulated voltage signals V_{SMA} and V_{SMB} as inputs to the switching network 1500.

Switching network 1500 comprises a first plurality of outputs 1502a-1502N each of which may be coupled to one or more of a second plurality of rf amplifiers (not shown in FIG. 15). In embodiments, the plurality of switching network outputs may be the same as the number of rf amplifiers such that there exists a one-to-one correspondence between the number of switching network outputs and RF amplifiers. In this case, each rf amplifier may be coupled to a respective one of the switching network outputs 1502a-1502N.

In the example embodiment of FIG. 15, switching network 1500 is illustrated as providing N outputs 1502a-1502N (where N is any integer greater than 1) at which respective ones of voltages V_{O1}-V_{ON} may be provided. The switching network outputs may be coupled to one or more bias terminals (e.g., a supply terminal) of one or more rf power amplifiers and thus output voltages V_{O1}-V_{ON} may be coupled to a bias terminal of one or more rf power amplifiers. In some embodiments, N may be equal to 2 (thus providing output voltages V_{O1}, V_{O2}). In some embodiments, N may be equal to 4 (thus providing output voltages V_{O1}-V_{O4}). In some embodiments, N may be equal to 6 (thus providing output voltages V_{O1}-V_{O6}). In some embodiments, N may be equal to 8 (thus providing voltages V_{O1}-V_{O8}). In some embodiments, N may be equal to 10 (thus providing voltages V_{O1}-V_{O10}).

For example, in one embodiment, two or more output ports may be coupled to provide output signals in some cases all N output signals V_{O1}-V_{ON} may be coupled to a bias terminal (e.g., a supply terminal) of a single rf power amplifier. In other embodiments, one or more or each output signal V_{O1}-V_{ON} may be coupled to its own, respective, rf power amplifier (i.e., a bias terminal of respective rf amplifiers). And in still other embodiments, one or more output amplifiers may be coupled to a single output terminal of switching network 1500, while other rf output amplifiers may be coupled to two or more output signals of switching network 1500.

The switches S₁-S₁₁ of switching network 1500 may be coupled to a controller (not shown) that can open and close the switches S₁-S₁₁ to control the output signals V_{O1}-V_{ON}. In this way, the switching network 1500 can be coupled across one or more PSN (and in some cases, configured to provide a signal path which bypasses one or more of the PSN). For example, when switch S₁ is closed, modulated voltage signal V_{SMA} is coupled to output 1502a at which voltage V_{O1} is provided. When switch si is open and switches S₂ and S₃ are closed, modulated voltage signal V_{SMA} is coupled through PSN 1503 (also referred to as filter network 1503) to output 1502a. And when switches S₁ and S₃ are open, the output signal V_{O1} at output 1502a is not connected to voltage signal V_{SMA}, and may be floating or may be tied to some other potential such as ground by circuitry not shown. Thus, switches S₁, S₂, and S₃ can be used to adaptively (or dynamically) in real time enable or disable filtering (performed by a filter network 1503) for output signal V_{O1}. It should be appreciated that filtering circuitry may be provided in a variety of different circuit configurations to provide filter characteristics selected to meet the needs of a particular application. Taking filter network (PSN) 1503 illustrative of filter networks 1504-1510, filter network 1503 comprises one or more electronic elements. In the example of FIG. 15 filter network 1503 comprises four electronic elements which are passive circuit elements (also sometimes referred to herein as a “passive component”). Filter networks 1503-1510 may have various passive or active circuit elements selected to suit the needs of a particular application. After reading the disclosure provided herein, one of ordinary skill in the art will understand how to design one or more filter networks to suit the needs of a particular application.

In some embodiments, a PSN can include one or more passive elements realized as discrete elements. In some embodiments, a PSN can include one or more passive elements realized on an IC or module. In some embodiments, a PSN can include one or more passive elements resulting from parasitic resistance, inductance, or capacitance.

In some embodiments, a PSN can include a resistor having a first terminal connected to the output of the hybrid supply generator/modulator, and a capacitor having a first terminal to the second terminal of the resistor and a second terminal connected to ground. In some embodiments, a PSN can include a capacitor having a first terminal connected to the output of the hybrid supply generator/modulator and a second terminal connected to ground, and a resistor having a first terminal connected to the first terminal of the capacitor.

Whether to connect or not a given PSN (e.g., one or more of filter networks 1503, 1508, 1510, etc.) between a hybrid supply generator/modulator (e.g., one or more of hybrid supply generator/modulators 1511a, 1511b) and an output (e.g., one of outputs 1502a-1502N) may depend upon a variety of factors including but not limited to: the rf frequency band in which the RF signal provided to the RF input of the power amplifier resides; the bandwidth of the RF signal provided to the RF input of the power amplifier; peak-to-average ratio of the RF signal provided to the RF input of the power amplifier; power level of the RF signal provided to the RF input of the power amplifier; other aspects or characteristics of the RF signal to be provided to the RF input of the PA; the mode of the supply modulation (e.g., digital envelope tracking vs. average power tracking vs. fixed supply) being used; and/or by the characteristics of an operating or application scenario (e.g., observed noise or amplifier behavior) among other factors.

Similarly, when switch S₄ is closed, modulated voltage signal V_{SMA} is coupled through filter network 1504 to output 1502b at which voltage V_{O2} is provided. When switch S₅ is closed, modulated voltage signal V_{SMA} is coupled through filter network 1506 to output 1502c. And when switch S₆ is closed, modulated voltage signal V_{SMB} is coupled through filter network 1506 to output 1502c. Thus, switches S₅ and S₆ may be used to select which modulated voltage signal V_{SMA} or V_{SMB} (or both in parallel) is coupled to provide an output signal at output 1502c.

When switch S₇ is closed, modulated voltage signal V_{SMB} is coupled through filter network 1508 to terminal 1502d is provided. It should be appreciated that one, some or all of filters 1503-1510 may be provided as reconfigurable filters. For example, filter 1508 comprises switch S₈. Switch S₈ is configured to change the filtering parameters (or characteristics) of filter network 1508. In this case, closing switch S₈ creates a short circuit signal path across inductor L8 thereby effectively removing inductor L8 from filter 1508, which will affect the transfer function of filter network 1508. In this way filter characteristics of filter 1508 may be changed (e.g., adaptively changed or “on-the-fly” or in real time) to suit the needs of a particular application or operating scenario. For example, it might be desirable to dynamically adjust the characteristics of the filter depending upon the rf band in which the signal will be transmitted by the power amplifier, by the bandwidth, peak-to-average ratio, power level, or other aspects of the signal to be transmitted, and by the mode of the supply modulation (e.g., digital envelope tracking vs. adaptive power tracking vs. fixed supply) being used, or by the characteristics of an operating or application scenario (e.g., observed noise or amplifier behavior) among other factors.

Switches S₉, may be switched between open and closed states to selectively couple modulated voltage signal V_{SMB} through filter 1510 to node 1512. Switches S₁₀, S₁₁ may be switched between open and closed states to couple node 1512 to either or both of outputs 1502N−1, 1502N at which respective ones of voltages VN−1, VN are provided. When switches S₉ and S₁₀ are closed, modulated voltage signal V_{SMB} is coupled through filter network 1510 to output 1502N−1 at which voltage VN−1 is provided. Similarly, when switches S₉ and S₁₁ are closed modulated voltage signal V_{SMB} is coupled through filter network 1510 to node 1512 at which voltage VN may be provided. When all three switches S₉, S₁₀, and S₁₁ are closed, modulated voltage signal V_{SMB} is coupled through filter network 1510 to both output terminals 1502N−1 and 1502N.

The signal paths created by switches S₁-S₁₁ in FIG. 15 are provided as examples. One skilled in the art will recognize that other configurations of signal paths and filtering parameters and characteristics are possible by changing the number, arrangement, and control of the switches in switching network 1500. For example, the switches S₁-S₁₁ may be operated or controlled (i.e., placed in an open or closed states) such either of modulated voltage signals V_{SMA}, V_{SMB} may be coupled to any of terminals 1502a-1502N. In general, switches within switching network 1500 may be configured to enable one or more on-die supply modulator output(s) to be routed to one or more power amplifier supply terminals; adjusting filtering of a provided modulator output (e.g., to provide a reconfigurable pulse shaping network); reconfigure how different (possibly spatially separated) filter stages are utilized in connecting one or more modulator outputs via one or more filter stages to one or more RF amplifiers; and turn-off switch(es) to enable a supply modulator output to be disconnected from a power amplifier and/or filter, or perform other tasks that modify and/or control the output signals that provide power to RF power amplifiers.

The particular manner in which the switching network 1500 is realized may depend upon the power level, voltage level and application space of the system in which the switching network is being used (e.g., an RF amplifier system). For some mobile device applications (e.g., a cellular phone, smart phone, tablet PC with cellular communication capabilities) it may be desirable to monolithically integrate electronic elements (e.g., circuit components) of both the supply generator and supply modulator and switching elements as well as portions of the ancillary circuits on a single semiconductor die (e.g., in a CMOS or BCD process) or IC. In some cases it may be desirable to integrate electronics such as the modulator(s) and switching network 1500 together with power amplifiers on a single die. Moreover, in some cases it may be advantageous to package the modulator, switches and some of the filter components within a single module and locate other filter components and the RF amplifier in a physically separated location. In still other applications it may be advantageous to package the modulator and some switches on a first die, and further switches on at least one additional die that is placed a relative distance from the first die. This second die may also contain one or more power amplifiers or be located physically close to power amplifier(s), e.g., in a module or co-located on a circuit board. In these latter cases, the switches on the first die can be used for some of the functions described above and may be placed close to one or more first filter stages, while the second die can also implement some of the functions described above and may be placed closer to one or more second filter stages. Communication lines may also be provided between the first die and the second die (or between a controller and the second die) to allow the configuration to be changed.

Although reference is sometimes made herein to particular materials, devices and/or components, it is appreciated that other materials, devices and/or components having similar functional and/or structural properties may be substituted where appropriate, and after reading the description provided herein, a person having ordinary skill in the art would understand how to select such materials, devices and/or components and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to an “embodiment” or “embodiments” indicate that the embodiment(s) described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within +20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

As used herein, the terms “processor” and “controller” are used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a digital signal processor (DSP), and/or in a discrete electronic circuit, which can be analog or digital. A processor or controller can include internal processors or modules that perform portions of the function, operation, or sequence of operations. Similarly, a module can include internal processors or internal modules that perform portions of the function, operation, or sequence of operations of the module. A single processor or other unit may fulfill the functions of several means recited in the claims.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

Other variations to the disclosed embodiments can be understood and effected by those skilled in the art in practicing the claimed invention, from a study of the drawings, the disclosure, and the appended claims.

The mere fact that certain measures are recited in mutually different dependent claims does not indicate that a combination of these measures cannot be used to obtain an advantage.

Any reference signs in the claims should not be construed as limiting the scope.

All publications and references cited herein are expressly incorporated herein by reference in their entirety.

1. A system comprising:
a hybrid supply generator/modulator comprising:
an input to receive an input voltage;
an output to provide a modulated voltage;
a multi-output regulation stage configured to provide two intermediate voltages having voltage levels different from each other, at least one of the two intermediate voltages synthesized from the input voltage; and
a multilevel converter configured to receive the two intermediate voltages and to generate the modulated voltage having a voltage level corresponding to one of the two intermediate voltage levels or at least one synthesized voltage level different from both intermediate voltage levels; and
circuitry coupled to the output of the hybrid supply generator/modulator and to a power supply terminal of at least one radio frequency (rf) amplifier, the circuitry configured to modify the modulated voltage supplied to the at least one rf amplifier.

2. The system of claim 1 wherein the circuitry comprises a disconnect switch configured to selectively supply a zero voltage level to the at least one rf amplifier.

3. The system of claim 1 wherein the circuitry comprises a disconnect switch configured to selectively isolate the output of the hybrid supply generator/modulator from the at least one rf amplifier.

4. The system of claim 3 wherein the disconnect switch is configured to be actuated in conjunction with enabling or disabling the rf amplifier.

5. The system of claim 1 wherein the circuitry comprises a pulse shaping network (PSN) configured to filter the modulated voltage.

6. The system of claim 5 wherein the PSN includes at least one passive element.

7. The system of claim 6 wherein the at least one passive element is realized as a discrete element.

8. The system of claim 6 wherein the at least one passive element is realized on an integrated circuit (IC) or module.

9. The system of claim 6 wherein the at least one passive element results from parasitic resistance, inductance, or capacitance.

10. The system of claim 5 wherein the PSN includes:
first and second inductors connected in series between the output of the hybrid supply generator/modulator and the power supply terminal of the at least one rf amplifier;
a capacitor having a first terminal connected between first and second inductors; and
a third inductor connected between a second terminal of capacitor and ground.

11. The system of claim 5 wherein the PSN includes:
a resistor having a first terminal connected to the output of the hybrid supply generator/modulator; and
a capacitor having a first terminal connected to a second terminal of the resistor and a second terminal connected to ground.

12. The system of claim 5 wherein the PSN includes:
a capacitor having a first terminal connected to the output of the hybrid supply generator/modulator and a second terminal connected to ground; and
a resistor having a first terminal connected to the first terminal of the capacitor.

13. The system of claim 5 wherein the circuitry further comprises a switching network.

14. The system of claim 13 wherein the switching network is configured such that in a first state, the switching network provides a first signal path having a first filter configuration between the output of the hybrid supply generator/modulator and the power supply terminal of the at least one rf amplifier, and in a second state, the switching network provides a second signal path having a second, different filter configuration between the output of the hybrid supply generator/modulator and the and the power supply terminal of the at least one rf amplifier.

15. The system of claim 13 wherein the switching network comprises at least one passive element having a first terminal connected to the output of the hybrid supply generator/modulator,
a switching network configured such that in a first state the switching network connects a second terminal of the at least one passive element to ground, and in a second state, the switching network disconnects the second terminal of the at least one passive element from ground.

16. The system of claim 13 wherein the switching network is coupled in a cascaded configuration with the hybrid supply generator/modulator.

17. The system of claim 13 wherein the switching network is coupled across the PSN and configured to selectively provide a signal path which bypasses the PSN.

18. The system of claim 13 wherein the switching network is coupled in parallel with a passive element of the PSN and configured to alter a transfer function of the PSN by selectively shorting at least one passive element.

19. The system of claim 13 wherein the switching network comprises plurality of switches and at least a first set of the plurality of switches are located on a first integrated circuit die and at least a second set of the plurality of switches are located on a second, different integrated circuit die.

20. A system comprising:
a hybrid supply generator/modulator comprising:
an input to receive an input voltage;
an output to provide a modulated voltage;
a multi-output regulation stage configured to provide two intermediate voltages having voltage levels different from each other, at least one of the two intermediate voltages synthesized from the input voltage; and
a multilevel converter configured to receive the two intermediate voltages and to generate the modulated voltage having a voltage level corresponding to one of the two intermediate voltage levels or at least one synthesized voltage level different from both intermediate voltage levels,
wherein the output of the hybrid supply generator/modulator is directly or indirectly coupled to a power supply input of at least one radio frequency (rf) amplifier.

21. A method for change a frequency response of circuit coupled to an output of a hybrid supply generator/modulator and to a radio frequency (rf) amplifier, the method comprising:
in a first state, configuring the circuit to provide a first signal path having a first filter configuration between the hybrid supply generator/modulator output and the rf amplifier input; and
in a second state, configuring the circuit to provide a second signal path having a second, different filter configuration between the hybrid supply generator/modulator output and the rf amplifier input.
